(19) United States
(12) Patent Application Publication
(10) Pub. No.: US 2023/0132196 A1
(43) Pub. Date: Apr. 27, 2023

(54) LIGHT RECEIVING APPARATUS, DISTANCE MEASUREMENT APPARATUS, AND LIGHT RECEIVING CIRCUIT

(71) Applicant: Sony Semiconductor Solutions Corporation, (US)

(72) Inventors: Kumiko Mahara, Kanagawa (JP); Osamu Ozawa, Tokyo (JP); Tomohiro Matsukawa, Kanagawa (JP); Yasuhiro Shinozuka, Kanagawa (JP)

(21) Appl. No.: 17/766,967

(22) PCT Filed: Oct. 13, 2020
(86) PCT No.: PCT/JP2020/038683

§ 371 Date: Apr. 6, 2022

(30) Foreign Application Priority Data
Nov. 1, 2019 (JP) 2019-200196

(51) Int. Cl. G01S 7/4861; G01S 7/497; G01S 7/4865; G01S 7/481; G01S 17/10

(52) U.S. Cl. CPC G01S 7/4861; G01S 7/497; G01S 7/4865; G01S 7/4816; G01S 17/10

(57) ABSTRACT

[Problem]

To provide a light receiving apparatus, a light receiving circuit, and a distance measurement apparatus which can detect a photon with high accuracy, irrespective of illuminance in the environment.

[Solution]

A light receiving apparatus according to the present disclosure includes a first light receiving circuit configured such that it is possible to switch a recharge method for a light receiving element, and a control circuit configured to control the recharge method for the first light receiving circuit on the basis of a signal outputted by the first light receiving circuit in a reaction with a photon.

### TECHNICAL FIELD

The present disclosure pertains to a light receiving apparatus, a distance measurement apparatus, and a light receiving circuit.

### BACKGROUND ART

In a plurality of fields such as in-vehicle and mobile, an application of techniques for measuring a distance to an object on the basis of a time of flight (ToF) for irradiation light from a light emitting element to be reflected by an object and return to a light receiving element is progressing. An avalanche photodiode (APD) is known as a light receiving element. In a Geiger-mode APD, a voltage greater than or equal to a breakdown voltage is applied across terminals, and an avalanche phenomenon occurs with an incidence of a single photon. An APD in which a single photon causes multiplication by the avalanche phenomenon is referred to as a single photon avalanche diode (SPAD).

In an SPAD, it is possible to stop the avalanche phenomenon by reducing the voltage across the terminals to the breakdown voltage. Stopping the avalanche phenomenon by reducing the voltage across terminals is referred to as quenching. When the voltage across the terminals of the SPAD is caused to recharge to a bias voltage which is greater than or equal to the breakdown voltage, it is then possible to detect a photon again.

### CITATION LIST

### Patent Literature

### [PTL 1]

Japanese Patent Laid-Open No. 2010-091377

### [PTL 2]

Japanese Patent Laid-Open No. 2014-081254

### [PTL 2]

Japanese Patent Laid-Open No. 2018-179732

### SUMMARY

### Technical Problem

A measurement of a distance according to ToF requires an apparatus which supports a dynamic range for a wide range of brightness. However, in an environment with high illuminance, there are cases where SPAD recharge ceases to be possible, or it takes time to recharge. Accordingly, a dead time in which a photon detection is not possible lengthens. It is desirable to shorten the dead time in order to perform the distance measurement with high accuracy.

Accordingly, the present disclosure provides a light receiving apparatus, a light receiving circuit, and a distance measurement apparatus which can detect a photon with high accuracy, irrespective of the illuminance in the environment.

### Solution to Problem

A light receiving apparatus according to one aspect of the present disclosure may include a first light receiving circuit configured so that it is possible to switch a recharge method for a light receiving element, and a control circuit configured to control the recharge method for the first light receiving circuit on the basis of a signal outputted by the first light receiving circuit in a reaction with a photon.

The recharge method may include at least one of passive recharge, active recharge, or a combination of passive recharge and active recharge.

The recharge method may include at least one of a recharge current for a time of passive recharge operation, or a time delay at which a reset pulse is generated at a time of active recharge operation.

It may be that a plurality of the first light receiving circuits is provided, and the control circuit is configured to control the recharge method for at least one of the first light receiving circuits on the basis of the signal outputted by the plurality of the first light receiving circuits.

It may be that a measurement circuit configured to count the number of reactions in the plurality of the first light receiving circuits is further provided, and the control circuit is configured to control the recharge method for at least one first light receiving circuit on the basis of the number of reactions.

It may be that an error detector configured to perform an error determination on the basis of a waveform of the signal outputted by the first light receiving circuit is further provided, and the control circuit is configured to control the recharge method for at least one of the first light receiving circuits on the basis of the number of error determinations for the signal outputted by the plurality of the first light receiving circuits.

The error detector may be configured to perform an error determination for at least one of the signal having a pulse width in excess of a first threshold, or the signal having an interval between pulses of less than a second threshold.

An error correction circuit configured to perform an error determination on the basis of the waveform of the signal outputted by the first light receiving circuit and correct the waveform of the signal for which the error determination is performed may be further provided.

The error correction circuit may be configured to perform an error determination for at least one of the signal having a pulse width in excess of a first threshold, or the signal having an interval between pulses of less than a second threshold.

The control circuit may be configured to control the recharge method for at least one of the first light receiving circuits on the basis of the number of error determinations for the signal outputted by the plurality of the first light receiving circuits.

The control circuit may be configured to control the recharge method for the first light receiving circuit for each region of a captured image.

The control circuit may be configured to control the recharge method for the plurality of the first light receiving circuits on the basis of the signal outputted by the first light receiving circuit that corresponds to a partial region of a captured image.

A plurality of second light receiving circuits configured to perform a passive recharge operation may be further provided.

It may be that the first light receiving circuit is connected to a first pixel, and each second light receiving circuit is connected to a second pixel having a smaller light receiving surface or an opening surface than a light receiving surface or an opening surface of the first pixel.

The light receiving element may be an avalanche photodiode.

A distance measurement apparatus according to one aspect of the present disclosure may include a light emitting element, a plurality of light receiving circuits configured such that a recharge method for a light receiving element can be switched, and a control circuit configured to, in a time period in which the light emitting element is not emitting light, control the recharge method for at least one of the light receiving circuits on the basis of a signal outputted by the plurality of the light receiving circuits in reaction to a photon.

A light receiving circuit according to one aspect of the present disclosure may include a light receiving element, a load element connected to a reference potential, a first switch connected between the load element and the light receiving element, an inverter connected to a first signal line between the first switch and the light receiving element via a second signal line, a first transistor connected to the reference potential, a second switch connected between the first transistor and the second signal line, and a pulse generator connected to a third signal line that is a subsequent stage for the inverter, and a first control electrode of the first transistor.

The pulse generator may be configured to output a pulse to the first control electrode according to a voltage of the third signal line.

The pulse generator may be configured to, when a voltage level of the third signal line changes, output a pulse to the first control electrode with a time delay.

It may be that a second transistor connected to the reference potential, and a third switch connected between the second transistor and the second signal line are further provided, and a second control electrode of the second transistor is connected to the third signal line.

### BRIEF DESCRIPTION OF DRAWINGS

FIG. 1 is a block view illustrating an example of a distance measurement apparatus.

FIG. 2 is a view which schematically illustrates an example of a distance measurement by using a distance measurement apparatus.

FIG. 3 is a circuit diagram illustrating an example of a light receiving circuit.

FIG. 4 is a graph illustrating an example of a voltage waveform in a light receiving circuit.

FIG. 5 is a graph illustrating an example of a histogram for a low illuminance environment.

FIG. 6 is a graph illustrating an example of a histogram for a high illuminance environment.

FIG. 7 is a graph illustrating an example of an ideal histogram for a high illuminance environment.

FIG. 8 is a view schematically illustrating an example of a light receiving apparatus according to the present disclosure.

FIG. 9 is a circuit diagram illustrating an example of a circuit according to the present disclosure.

FIG. 10 is a table indicating an example of switch settings for the circuit according to the present disclosure.

FIG. 11 is a graph illustrating an example of a voltage waveform in the circuit according to the present disclosure.

FIG. 12 is a circuit diagram illustrating an example of a configuration of a pulse generator.

FIG. 13 is a graph illustrating an example of a relation between the number of reacting SPADs and a threshold.

FIG. 14 is a table indicating an example of correspondence between the number of reacting SPADs and a selected operation mode.

FIG. 15 is a flow chart illustrating an example of processing for determining a distance measurement condition.

FIG. 16 is a plan view illustrating an example of correspondence between pixels and a recharge circuit.

FIG. 17 is a plan view illustrating an example of correspondence between pixels and a recharge circuit.

FIG. 18 is a view illustrating an example of setting a distance measurement condition for each image region.

FIG. 19 is a view illustrating an example of setting a distance measurement condition for each image.

FIG. 20 is a block view illustrating an example of a light receiving apparatus.

FIG. 21 is a schematic view illustrating an example of a light receiving apparatus according to a first modification.

FIG. 22 is a graph illustrating an example of an error detection for voltage waveforms.

FIG. 23 is a table indicating an example of operation modes in the first modification.

FIG. 24 is a flow chart illustrating an example of processing for determining a distance measurement condition, according to the first modification.

FIG. 25 is a schematic view illustrating an example of a light receiving apparatus according to a second modification.

FIG. 26 is a graph illustrating an example of processing for correcting a voltage waveform in the second modification.

FIG. 27 is a graph illustrating an example of processing for correcting a voltage waveform in the second modification.

FIG. 28 is a circuit diagram illustrating an example of a circuit according to a third modification.

FIG. 29 is a circuit diagram illustrating an example of an active recharge circuit.

FIG. 30 is a block view illustrating an example of a distance measurement apparatus.

FIG. 31 is a block diagram depicting an example of schematic configuration of a vehicle control system.

FIG. 32 is a diagram of assistance in explaining an example of installation positions of an outside-vehicle information detecting section and an imaging section.

### DESCRIPTION OF EMBODIMENTS

With reference to the attached drawings, description is given below in detail regarding suitable embodiments according to the present disclosure. Note that, in the present specification and the drawings, the same reference symbols are added to components having substantially the same functional configurations, whereby duplicate explanation is omitted.

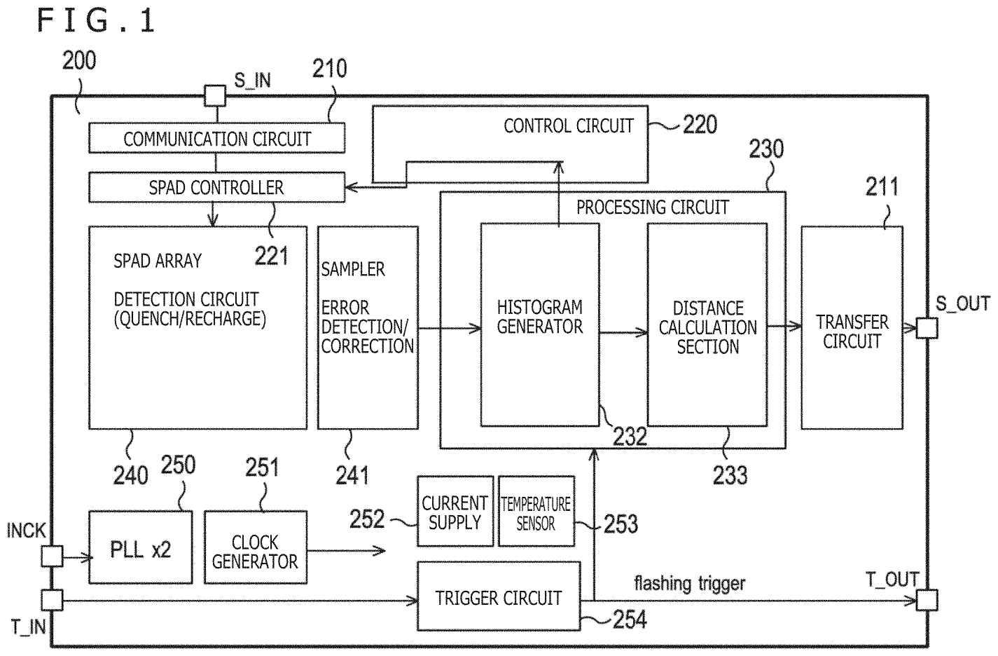

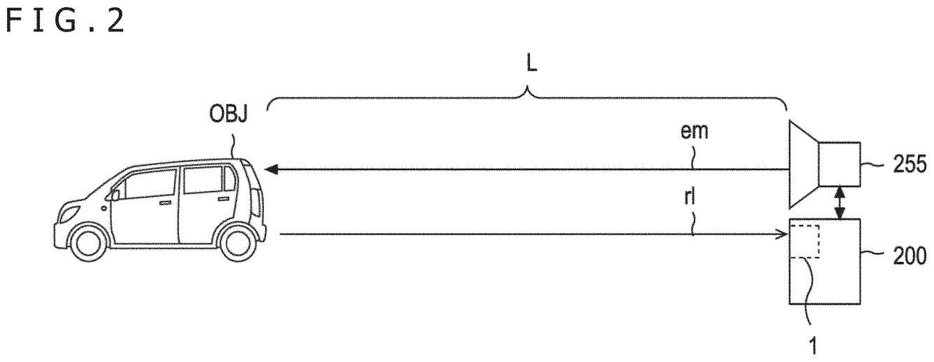

A block view in FIG. 1 illustrates an example of a distance measurement apparatus. In addition, FIG. 2 schematically illustrates an example of a distance measurement by using a distance measurement apparatus. A distance measurement apparatus 200 in FIG. 1 includes a communication circuit 210, a control circuit 220, a SPAD controller 221, a circuit block 240, a circuit block 241, a processing circuit 230, a transfer circuit 211, a PLL 250, a clock generator 251, a current source 252, a temperature sensor 253, and a trigger circuit 254. The processing circuit 230 includes, as internal components, a histogram generator 232 and a distance calculation section 233. In addition, the distance measurement apparatus 200 is, via a terminal T_OUT, connected to a light emitting element 255 in FIG. 2.

The communication circuit 210 and the transfer circuit 211 communicate with external circuits. The control circuit 220 controls each component of the distance measurement apparatus 200. The circuit block 240 corresponds to a detecting section 1 in FIG. 2. The circuit block 240 is mounted with, for example, a SPAD array, and light receiving circuits corresponding to each SPAD. The SPAD array includes a plurality of single photon avalanche diodes (SPADs). Each light receiving circuit is configured to output a pulse to a subsequent-stage circuit when a SPAD reacts with a photon. In addition, the light receiving circuit includes a circuit for quenching and recharging the SPAD. The SPAD controller 221 controls the light receiving circuits. The SPAD controller 221, for example, switches a switch in a light receiving circuit, controls a current value, and controls a pulse generation timing.

The circuit block 241, for example, includes samplers connected as a subsequent stage for respective light receiving circuits. Each sampler is referred to as a buffer, and digitalizes a signal inputted from a light receiving circuit. In addition, the circuit block 241 may include error detectors or error correction circuits. Details for error detectors and error correction circuits are described below. The trigger circuit 254 controls a light emission timing for the light emitting element 255.

The histogram generator 232 samples a voltage level for the digitalized output signal from each light receiving circuit, and generates a histogram. The histogram generator 232 may repeat a sampling operation a plurality of times, and generate a histogram. The sampling operation is performed a plurality of times, whereby it becomes possible to identify disturbance light and reflected light r1 for light irradiated from a light emitting element. The histogram generator 232, when generating a histogram, may perform a calculation such as an average of measurement results over a plurality of times. The distance calculation section 233 calculates the distance between the distance measurement apparatus 200 and an object on the basis of information pertaining to an irradiation time t0 for light transferred from the trigger circuit 254 and a peak time t1 for a histogram. For example, letting a speed of light be c, it is possible to obtain the distance between the distance measurement apparatus 200 and an object OBJ by the formula L=c/2 (t1−t0). In the formula, t1−t0 corresponds to the time of flight. By using the transfer circuit 211, information which includes a calculated distance may be transferred to an external circuit.

For example, it is possible to implement components for the processing circuit 230, including the histogram generator 232 and the distance calculation section 233, according to a hardware circuit such as an FPGA (Field Programmable Gate Array) or an ASIC (Application Specific Integrated Circuit). However, the functionality of the processing circuit 230 may be implemented by a CPU (central processing unit), and a program executed by the CPU. In this case, the processing circuit 230 may include a memory or a storage for storing the program and data necessary to execute the program.

Note that the distance measurement apparatus 200 in FIG. 1 is merely an example of the configuration of a distance measurement apparatus. Accordingly, the configuration of a distance measurement apparatus according to the present disclosure may differ to that of the distance measurement apparatus 200. The distance measurement apparatus does not need to include all the components of the distance measurement apparatus 200. For example, the distance measurement apparatus may omit at least one of the PLL 250, the clock generator 251, the current source 252, the temperature sensor 253, the trigger circuit 254, and the communication circuit 210. In addition, other components may be added, or these other components may be omitted.

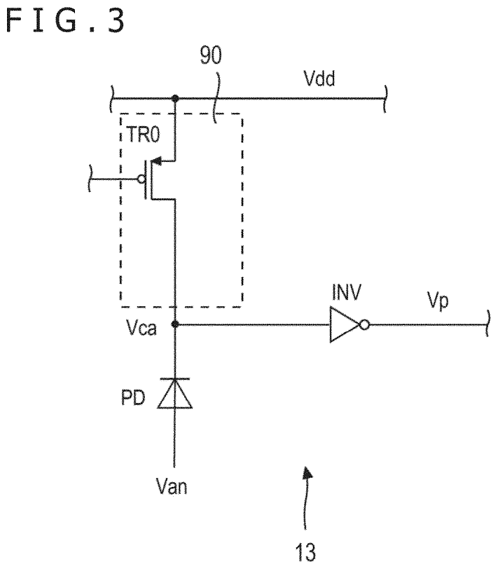

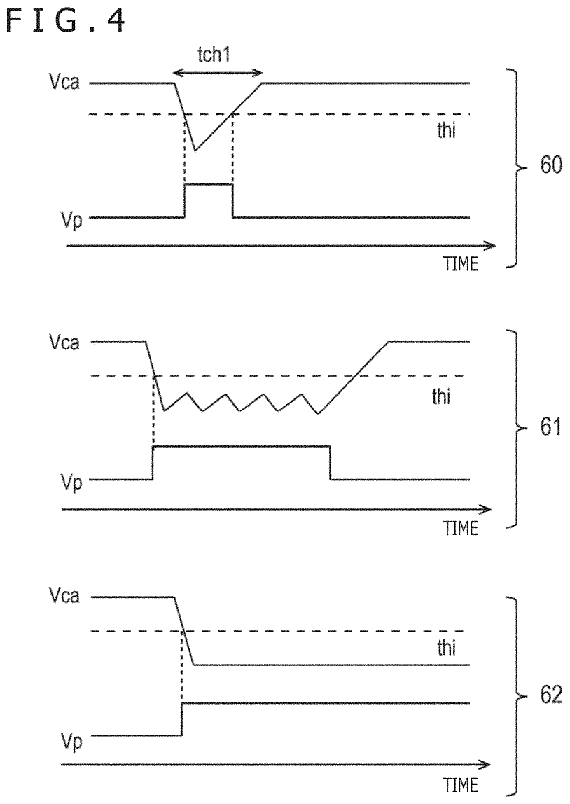

The circuit diagram in FIG. 3 illustrates an examples of a light receiving circuit used in a photon detection. In addition, a graph in FIG. 4 illustrates an example of voltage waveforms in a light receiving circuit. A circuit 13 in FIG. 3 includes a photodiode PD, a transistor TR0, and an inverter INV. The transistor TR0 is a PMOS transistor. It is possible to use a SPAD, for example, as the photodiode PD. The source for the transistor TR0 is connected to a power supply potential Vdd. A drain of the transistor TR0 is connected to a cathode of the photodiode PD. A voltage Van is applied to an anode of the photodiode PD. By the voltage Van, a reverse voltage greater than or equal to the breakdown voltage is applied over the terminals of the photodiode PD. The drain of the transistor TR0 and the cathode of the photodiode PD are connected to an input side of the inverter INV. In addition, a subsequent-stage circuit such as a buffer is connected to an output side of the inverter INV.

The transistor TR0 is an example of a load element 90 for the circuit 13. However, the configuration of a load element may differ from this. For example, as a load element, a resistor may be used, or a result of combining a transistor and a resistor may be used.

When a photon is incident on the photodiode PD and the current flowing between the terminals of the photodiode PD increases due to avalanche multiplication, a cathode potential Vca decreases according to a voltage drop at the load element 90. When the voltage across the terminals of the photodiode PD decreases to the breakdown voltage, the avalanche phenomenon stops and the current flowing between the terminals of the photodiode PD decreases. As a result, the voltage across the terminals of the photodiode PD takes a value greater than or equal to the breakdown voltage, and it becomes possible to detect a photon again (Vca in a graph 60). In contrast, the inverter INV outputs a HIGH (positive polarity) pulse (Vp in the graph 60) in a time period in which the cathode potential Vca is less than or equal to a threshold thi. The circuit 13 outputs a pulse when a photon is detected, and therefore it is possible to perform various processing such as counting photons, generating a histogram, and calculating a time of flight in subsequent-stage circuits.

Note that a circuit for performing an operation as illustrated in the graph 60 is referred to as a passive recharge circuit. The circuit 13 described above is an example of a passive recharge circuit. As a passive recharge circuit, a circuit having a configuration different to that of the circuit 13 may be used. For example, a circuit resulting from inverting polarities may be used. In addition, a circuit resulting from adding another element to the circuit 13 may be used. When a passive recharge circuit is used, it is possible to suppress power consumption.

After the photodiode PD reacts with a photon, the photodiode PD cannot detect a photon in a time period which is for causing the avalanche phenomenon to stop (quench) and recharging the voltage across the terminals of the photodiode PD to greater than or equal to the breakdown voltage again. This time period is referred to as a dead time. The number of SPADs installed in an apparatus is increased, whereby it is possible to reduce the impact of the dead time. This is because, if there is a sufficient number of SPADs, it is possible for other SPADs to compensate for the detection ability of some SPADs which have entered the dead time.

In a passive recharge circuit, a recharge current which flows through the load element 90 is increased, whereby it is possible to shorten the dead time to a certain level. However, when the recharge current is increased too much, the voltage across the terminals of the photodiode PD ceases to decrease to the breakdown voltage, and therefore it ceases to be possible to perform quenching (Vca in a graph 62). At this time, because the output voltage of the inverter INV gets stuck, it becomes difficult to detect a photon.

In addition, in a high illuminance environment, there is a possibility for the photodiode PD to re-react with a photon from disturbance light before the cathode potential Vca rises to a voltage higher than the threshold for the inverter INV. Accordingly, there is a delay for a rise of the cathode potential Vca, and the dead time lengthens. In addition, a pulse width outputted by the inverter INV becomes too large (graph 61). When the pulse width gets too large, it becomes difficult for processing such as the distance measurement to be performed by a subsequent-stage circuit.

Next, description is given regarding an example of a histogram generated by a histogram generator.

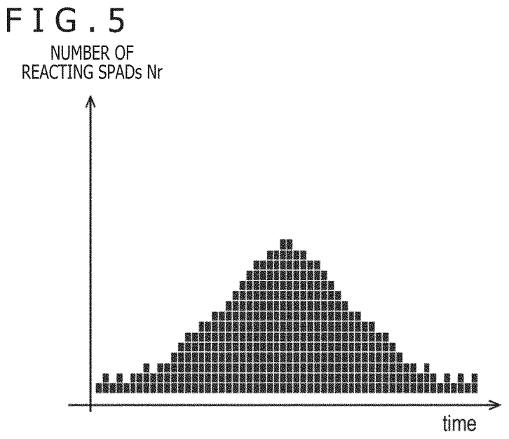

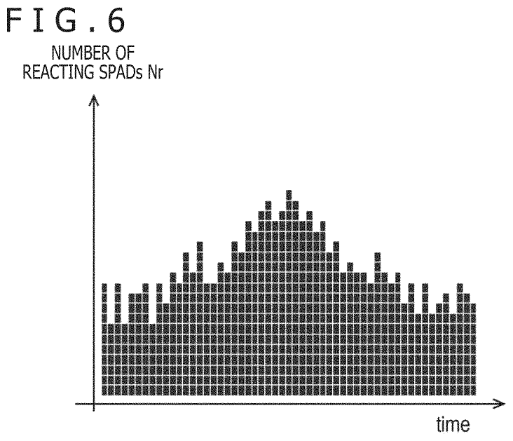

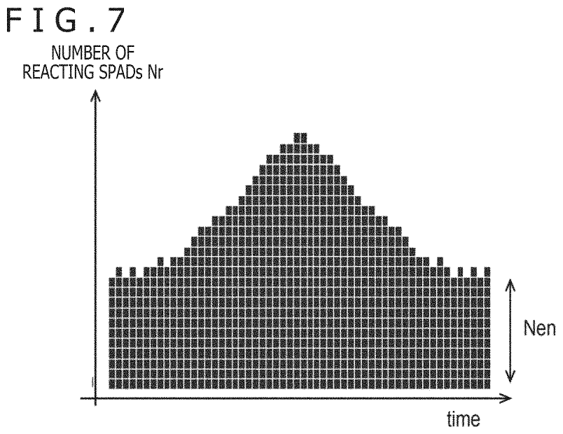

A graph in FIG. 5 illustrates an example of a histogram generated in a low illuminance environment. A graph in FIG. 6 illustrates an example of a histogram generated in a high illuminance environment. In each graph, a vertical axis indicates the number of reacting SPADs. In addition, a horizontal axis indicates a time difference from a light emission time for the light emitting element 255. When the illuminance of disturbance light is low, it is possible to generate a histogram in which a peak corresponding to reflected light r1 is clear (FIG. 5). However, in a high illuminance environment, there is a higher probability of a SPAD reacting with a photon from disturbance light instead of a photon from the reflected light r1. In addition, as illustrated in FIG. 4 described above, there is a trend for the dead time of a SPAD to lengthen in a high illuminance environment. Accordingly, because the number of SPADs which cannot react with a photon increases, a clear peak will cease to appear in the histogram (FIG. 6). Ideally, even in a high illuminance environment, it is desirable to be able to generate a histogram resulting from shifting the histogram in FIG. 5 upward by the number of photons corresponding to disturbance light, as illustrated in a graph in FIG. 7.

It is envisioned that the photon detection by a SPAD is performed in various illuminance environments, such as outside with sunny weather, at night, or inside a tunnel. In order to perform highly-accurate distance measurement irrespective of the illuminance of the environment, it is necessary to have a technique for a highly-accurate detection of a photon in a dynamic range for a wide range of brightness.

Description is given below regarding a light receiving circuit and a light receiving apparatus according to the present disclosure.

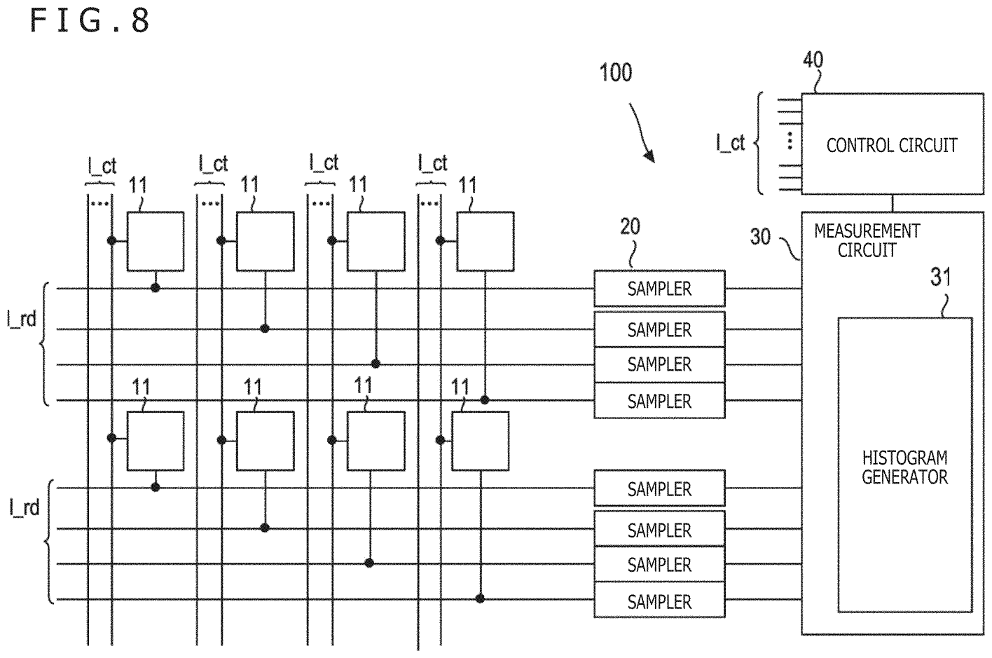

FIG. 8 schematically illustrates an example of a light receiving apparatus according to the present disclosure. A light receiving apparatus 100 in FIG. 8 includes a plurality of light receiving circuits 11, a plurality of samplers 20, a measurement circuit 30, and a control circuit 40. A light receiving circuit 11 includes a SPAD and a light receiving circuit. The measurement circuit 30 includes a histogram generator 31 as an internal component.

The plurality of light receiving circuits 11 is, for example, disposed in the circuit block 240 of the distance measurement apparatus 200 (FIG. 1). The plurality of samplers 20 are, for example, disposed in the circuit block 241. The measurement circuit 30 corresponds to the processing circuit 230, for example. The control circuit 40, for example, corresponds to the control circuit 220 and the SPAD controller 221.

Each light receiving circuit 11 is connected to a subsequent stage sampler 20 via a signal line l_rd. The subsequent stage of each sampler 20 is connected to the measurement circuit 30. The measurement circuit 30 is connected to the control circuit 40. The control circuit 40 is connected to each light receiving circuit 11 via a signal line l_ct. Note that, in FIG. 8, a plurality of signal lines l_ct is illustrated, but the number of signal lines for control does not matter. For example, the control circuit 40 may control a plurality of light receiving circuits 11 by one signal line.

When a SPAD reacts with a photon, the light receiving circuit 11 outputs a pulse to the signal line l_rd. The sampler 20 digitalizes a signal which includes the pulse. The histogram generator 31 generates a histogram on the basis of pulses included in signals inputted from respective samplers.

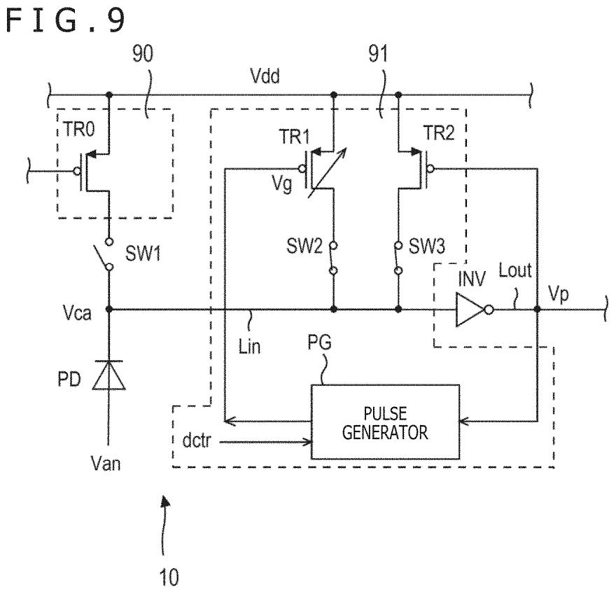

The circuit diagram in FIG. 9 illustrates an example of a circuit according to the present disclosure. A circuit 10 in FIG. 9 includes a photodiode PD, a switch SW1, a transistor TR0, a transistor TR1, a switch SW2, a transistor TR2, a switch SW3, an inverter INV, and a pulse generator PG. The transistor TR0, the transistor TR1, and the transistor TR2 are each a PMOS transistor. It is possible to use a SPAD, for example, as the photodiode PD.

The switch SW1, the switch SW2, and the switch SW3 are implemented by MOS transistors, for example. For example, it is possible to connect the gate of each MOS transistor to the control circuit 40. In this case, the control circuit 40 turns the switches on/off by controlling the voltage applied to the gate of each MOS transistor. Note that the gate of the transistor TR0 may be connected to the control circuit 40. In this case, the control circuit 40 can control the voltage applied to the gate of the transistor TR0 and adjust a resistance between the source and the drain of the transistor TR0.

The source for the transistor TR0 is connected to a power supply potential Vdd. The switch SW1 is connected between the drain of the transistor TR0 and the cathode of the photodiode PD. A voltage Van is applied to the anode of the photodiode PD. It is possible to determine a value for the voltage Van such that a reverse voltage greater than or equal to the breakdown voltage is applied across the terminals of the photodiode PD. The input terminal for the inverter INV is, via a signal line Lin, connected to the cathode of the photodiode PD and the switch SW1.

The source of the transistor TR1 and the source of the transistor TR2 are both connected to a power supply potential Vdd. The switch SW2 is connected between the drain of the transistor TR1 and the signal line Lin. Meanwhile, the switch SW3 is connected between the drain of the transistor TR2 and the signal line Lin. The output terminal of the inverter INV is, via a signal line Lout, connected to the gate of the transistor TR2 and the input terminal of the pulse generator PG. The output terminal of the pulse generator PG is connected to the gate of the transistor TR1.

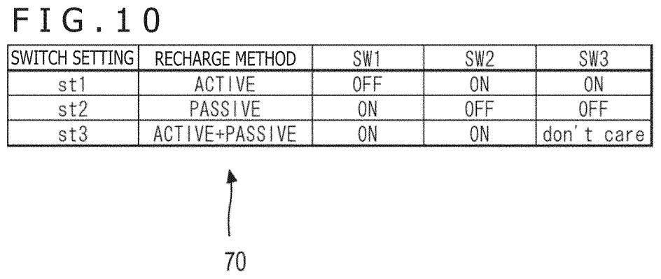

The table in FIG. 10 indicates an example of switch settings for the circuit 10. As illustrated in a table 70 in FIG. 10, in the circuit 10, it is possible to switch a method of recharging the photodiode PD according to a switch setting. When the switch SW1 is turned off and the switch SW2 and the switch SW3 are turned on, it is possible to cause the circuit 10 to perform an active recharge (switch setting st1). This is a switch setting for performing an active recharge in the circuit 10 illustrated in FIG. 9. When the switch SW1 is turned on and the switch SW2 and the switch SW3 are turned off, it is possible to cause the circuit 10 to perform a passive recharge (switch setting st2). In this case, the circuit 10 performs similar operation to that of the circuit 13 (a passive recharge circuit) in FIG. 3. Furthermore, when the switch SW1 and the switch SW2 are turned on, it is possible to cause the circuit 10 to perform both active recharge and active recharge (switch setting st3). In this case, the switch SW3 may be turned on or may be turned off.

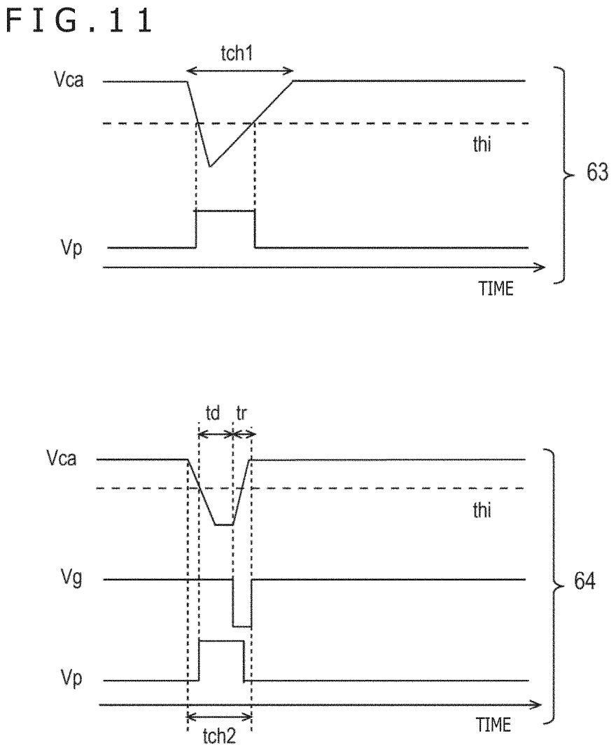

The graphs in FIG. 11 illustrates examples of voltage waveforms in the circuit 10. A graph 63 in FIG. 11 corresponds to a voltage waveform in a case where passive recharge is performed in the circuit 10. In contrast, a graph 64 corresponds to a voltage waveform in a case where active recharge is performed in the circuit 10. Note that Vg in the graph 64 indicates the gate voltage of the transistor TR1. In all of the graphs, the horizontal axis indicates time.

Description is given regarding operation for when an active recharge is caused in the circuit 10 (at a time of the switch setting st1). When a photon is incident on the photodiode PD and the current flowing between the terminals of the photodiode PD increases due to avalanche multiplication, the cathode potential Vca decreases according to a voltage drop across the source and the drain for the transistor TR1 and the transistor TR2. A case in the avalanche phenomenon stops (quenches) when the voltage across the terminals of the photodiode PD decreases to the breakdown voltage is similar to the case in which passive recharge is performed.

The inverter INV outputs a HIGH (positive polarity) pulse (Vp in the graph 64) in a time period in which the voltage of the signal line Lin is less than or equal to the threshold thi. On the basis of the pulse, the subsequent-stage measurement circuit 30 can execute various processing. Because the voltage of the signal line Lin is LOW, the voltage of the signal line Lout on the output side of the inverter INV becomes HIGH. When a HIGH signal is inputted to the pulse generator PG, a LOW (negative polarity) pulse is outputted after a time delay td. Accordingly, a LOW voltage is applied to the gate of the transistor TR1, and between the source and the drain of the transistor TR1 is turned on. At Vg of the graph 64, a LOW pulse is outputted over a time period tr. As a result, the cathode potential Vca is lifted up by the power supply potential Vdd, and the photon detection by the photodiode PD becomes possible again.

When the voltage of the signal line Lin becomes HIGH due to a recharge, the voltage of the signal line Lout on the output side of the inverter INV becomes LOW. At this time, a LOW voltage is applied to the gate of the transistor TR2, and between the source and the drain of the transistor TR2 is turned on. In such a manner, the transistor TR2 latches a state of the transistor TR1. By the transistor TR2, it is possible to suppress occurrence of a through current and prevent the cathode potential Vca becoming indefinite.

Note that, in a case where not just the switch SW2 and the switch SW3 but the switch SW1 is also turned on (switch setting st3), the voltage drop between the source and the drain of the transistor TR0 also contributes to quenching of the photodiode PD. A case in the voltage across the terminals of the photodiode PD rises when the current flowing between the terminals of the photodiode PD decreases due to the quenching is similar to with the circuit 13 in FIG. 3.

From among the circuit 10, a portion which includes the transistor TR1, the transistor TR2, the switch SW2, the switch SW3, and the pulse generator PG corresponds to an active recharge circuit 91. In addition, from among the circuit 10, a portion which includes the transistor TR0 (load element 90) and the switch SW1 corresponds to a passive recharge circuit. The circuit 10 is an example of a light receiving circuit which includes a passive recharge circuit and an active recharge circuit, and is able to switch recharge methods.

Note that a circuit having a configuration different to that of the circuit 10 (FIG. 9) may be used. For example, a circuit resulting from adding another element to the circuit 10 may be used. In addition, a circuit resulting from inverting polarities in the circuit 10 may be used. In a case where a circuit resulting from inverting polarities is used, a PMOS transistor may be replaced by an NMOS transistor. In addition, when polarities in the circuit 10 are inverted, a positive bias voltage is applied to the cathode of the photodiode PD. Note that it is possible to employ a configuration in which polarities are inverted for other circuits described in the present specification, with no limitation to the circuit 10.

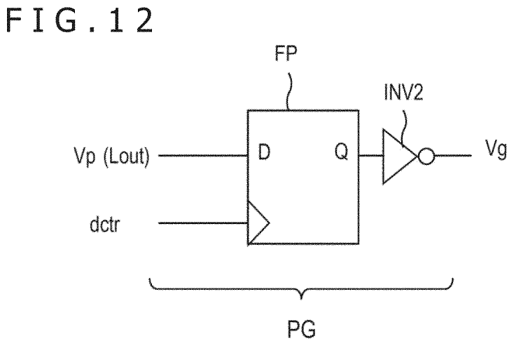

The circuit diagram in FIG. 12 illustrates an example of a configuration of a pulse generator. The pulse generator PG in FIG. 12 includes a flip flop FP and an inverter INV2. The flip flop FP is a D flip flop. The signal line Lout is connected to a D terminal of a flip flop F1. A signal line dctr is connected to a clock terminal of the flip flop F1. The inverter INV2 is connected between the Q terminal of the flip flop F1 and the gate of the transistor TR1.

In the pulse generator PG in FIG. 12, by controlling the clock signal supplied on the signal line dctr, it is possible to change the time delay td from when the voltage of the signal line Lout becomes the HIGH level until the voltage Vg is caused to change to the LOW level. For example, when the interval between pulses in the clock signal is increased, it is possible to increase the time delay td. In addition, when the interval between pulses in the clock signal is decreased, it is possible to decrease the time delay td. If the pulse generator PG in FIG. 12 is used, it becomes easy to control time delay according to the clock signal which is supplied from outside. For example, it is possible for the control circuit 40 or the clock generator 251 to supply a clock signal to the signal line dctr.

Note that the circuit in FIG. 12 is merely an example of the pulse generator PG. Accordingly, a pulse generator having a configuration different to this may be used. For example, a pulse generator may be implemented according to an inverter chain. In addition, a pulse generator may be implemented by combining a delay device and a logical operation element. In other words, a pulse generator with any circuit configuration may be used if it is possible to output a pulse to the gate of the transistor TR1 with a time delay after the level of the input voltage changes.

Next, description is given for operation of a light receiving apparatus according to the present disclosure, assuming that the circuit 10 in FIG. 9 is implemented as each light receiving circuit 11 in FIG. 8.

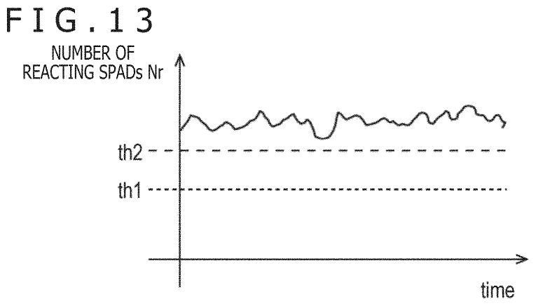

The graph in FIG. 13 illustrates an example of a histogram generated by the light receiving apparatus according to the present disclosure in order to measure disturbance light. The vertical axis of the graph in FIG. 13 corresponds to the number Nr of reacting SPADs. Meanwhile, the horizontal axis of the graph corresponds to a photon detection time. In order to measure the illuminance of the environment (disturbance light), the measurement circuit 30 measures the number of reacting SPADs in the light receiving apparatus 100 in a time period in which the light emitting element is not emitting light. In addition, the histogram generator 31 may be used to generate the histogram as illustrated in FIG. 13. The graph in FIG. 13 indicates a threshold th1 and a threshold th2 by broken lines.

The measurement circuit 30 transfers the number Nr of reacting SPADs to the control circuit 40. Then, the control circuit 40 can compare the number Nr of reacting SPADs with the threshold th1 and the threshold th2, and determine a recharge method. In the recharge method, passive recharge, active recharge, or a combination of passive recharge and active recharge is designated, for example. In addition, a parameter for a time of a recharge operation may be designated in the recharge method. Examples of a parameter for the time of a recharge operation include the time delay td at which a pulse for active recharge is generated, or a recharge current for a time of passive recharge. However, another type of setting value may be designated in a parameter. In addition, there is no need for all parameters for a time of a recharge operation to be able to be designated. For example, in a case where there is use of a circuit having a fixed time delay td at which the pulse for active recharge is generated or a circuit in which dynamic control of the recharge current is not possible, these parameters may be excluded from being subject to control.

Typically, the number Nr of reacting SPADs is estimated to correlate with the illuminance of the environment. Accordingly, if the number Nr of reacting SPADs is large, it is possible to estimate that the light receiving apparatus 100 has been installed in an environment having high illuminance. Conversely, if the number Nr of reacting SPADs is small, it is possible to estimate that the light receiving apparatus 100 has been installed in an environment having low illuminance.

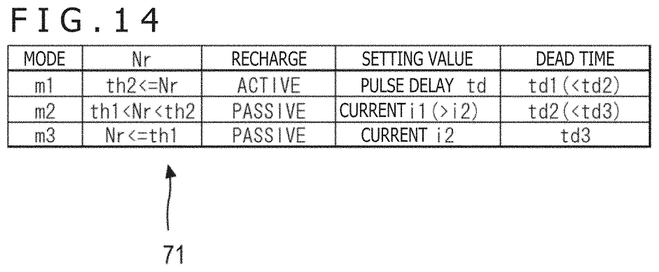

The table in FIG. 14 indicates an example of correspondence between the number of reacting SPADs and a selected operation mode. Referring to a table 71 in FIG. 14, a different operation mode is selected according to the number of reacting SPADs. For example, in a case where the number Nr of reacting SPADs is greater than or equal to the threshold th2, active recharge is performed (mode m1). In addition, in a case where the number Nr of reacting SPADs is less than the threshold th2, passive recharge is performed. In a case where the number Nr of reacting SPADs is greater than the threshold th1 and less than the threshold th, passive recharge according to a recharge current i1 is performed (mode m2). In a case where the number Nr of reacting SPADs is less than or equal to the threshold th1, passive recharge is performed according to a recharge current i2 which is smaller than i1 (mode m3).

Typically, active recharge enables the dead time to be shortened more than passive recharge. Accordingly, active recharge can be said to be a recharge method suitable for a high illuminance environment. In contrast, passive recharge has an advantage of being able to suppress power consumption more than active recharge. In a case of passive recharge, having a large recharge current enables the dead time to be shortened. Accordingly, in the example of the table 71, it is expected that the dead time for a SPAD is shorter in the order of the mode m3, the mode m2, and the mode m1.

The more that a mode can be expected to shorten the dead time, the more that electric power is required. Accordingly, it can be said that the dead time and power consumption for a SPAD are in a trade-off relation. Accordingly, as exemplified in the table 71, it is possible to select an optimal operation mode for which a balance has been achieved between the dead time and power consumption, according to the number Nr of reacting SPADs which has a correlation with the illuminance of the environment. In such a manner, when a mode which defines a recharge method including parameters is used, it is possible to avoid the complication of processing executed by the measurement circuit 30 and the control circuit 40.

Note that the control circuit 40 may compare the number of reacting SPADs obtained in one measurement with a threshold. In addition, the control circuit 40 may compare a representative value based on the number of reacting SPADs obtained in a plurality of measurements with a threshold. For example, the control circuit 40 may compare an average of the number of reacting SPADs measured a plurality of times with a threshold. In addition, the control circuit 40 may compare the number of reacting SPADs with a threshold each time measurement is performed, and select the operation mode on the basis of a determination result having the highest frequency.

Switching of modes indicated in the table 71 is merely an example of a method of changing the recharge method for the light receiving circuit 11. The recharge method for a light receiving circuit may be changed according to a method different to that for the table 71. For example, it is possible to select active recharge in a case where the number of reacting SPADs exceeds a threshold t_rch, and select passive recharge in a case where the number of reacting SPADs is less than or equal to the threshold t_rch. In a case where there is a parameter that can be adjusted in the light receiving circuit 11, it is possible to determine the parameter on the basis of the number Nr of reacting SPADs. For example, the pulse delay or the recharge current may be determined by using a function which takes the number Nr of reacting SPADs as a variable. In this case, it is possible to use a function in which the value of the pulse delay decreases the greater the number Nr of reacting SPADs. In addition, it is possible to use a function in which the value of the recharge current increases the greater the number Nr of reacting SPADs.

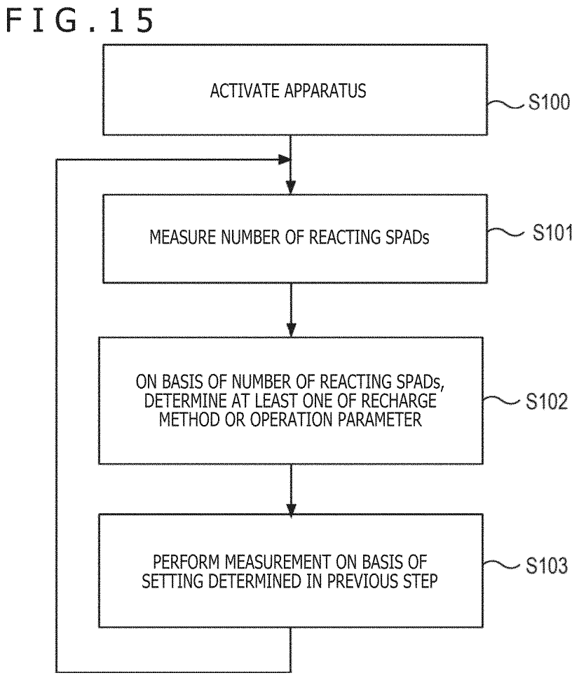

A flow chart in FIG. 15 illustrates an example of processing for determining a distance measurement condition. The processing is described below with reference to the flow chart in FIG. 15. A distance measurement condition, for example, includes a recharge method used in the light receiving circuit 11.

At the start, electric power is supplied, and the light receiving apparatus 100 is activated (step S100). The light receiving apparatus 100 then measures the number Nr of reacting SPADs in a time period in which the light emitting element is not emitting light (step S101). Here, the measurement circuit 30 can count pulses outputted from the plurality of light receiving circuits 11 (for example, the circuit 10) to thereby obtain the number Nr of reacting SPADs. The measurement circuit 30 transfers the number Nr of reacting SPADs to the control circuit 40.

Next, the control circuit 40, on the basis of the number Nr of reacting SPADs, determines the recharge method to be used by the light receiving circuit 11 (step S102). Here, the control circuit 40 can, on the basis of the number Nr of reacting SPADs obtained by the measurement circuit 30, determine the recharge method to be used by the light receiving circuit 11. In step S102, for example, one of prescribed modes as in the table 71 in FIG. 14 may be selected.

The control circuit 40 (more specifically, the SPAD controller 221) transmits a control signal via the signal line l_ct. As a result, the light receiving circuit 11 can perform, for example, switching of a switch according to the recharge method. The measurement circuit 30 can perform a distance measurement on the basis of a setting determined in step S102 (step S103). After the processing of step S103 is executed, the processing of step S101 and thereafter may be executed again at a timing when the distance measurement (in other words, emission of light by the light emitting element) is not performed. As a result, it is possible to set the light receiving apparatus 100 in alignment with changes in illuminance of the environment.

A light receiving apparatus according to the present disclosure may include a first light receiving circuit configured so that it is possible to switch a recharge method for a light receiving element, and a control circuit configured to control the recharge method for the first light receiving circuit on the basis of a signal outputted by the first light receiving circuit in a reaction with a photon. In addition, the light receiving circuit according to the present disclosure may include a plurality of the first light receiving circuits. In this case, the control circuit is configured to control the recharge method for at least one first light receiving circuit on the basis of signals outputted by the plurality of the first light receiving circuits. As the light receiving element, it is possible to use an avalanche photodiode, for example. The photodiode PD described above is an example of a light receiving element. In addition, the circuit 10 (FIG. 9) is an example of the first light receiving circuit. However, the first light receiving circuit may be a circuit having a configuration different to this.

The recharge method for the light receiving element in the first light receiving circuit can include at least one of passive recharge, active recharge, or a combination of passive recharge and active recharge. In addition, the recharge method for the light receiving element in the first light receiving circuit may include at least one of a recharge current for a time of passive recharge operation, or a time delay at which a reset pulse is generated at a time of active recharge operation.

In addition, a light receiving apparatus according to the present disclosure may further include a measurement circuit configured to count the number of reactions in the plurality of first light receiving circuits. In this case, the control circuit is configured to control the recharge method for at least one first light receiving circuit on the basis of the number of reactions.

A distance measurement apparatus according to the present disclosure may include a light emitting element, a plurality of light receiving circuits, and a control circuit. Each light receiving circuit is configured so that it is possible to switch a recharge method for a light receiving element. The control circuit is configured to, in a time period in which the light emitting element is not emitting light, control the recharge method for at least one light receiving circuit on the basis of signals outputted by the plurality of light receiving circuits in reaction to a photon. As the light receiving element, it is possible to use an avalanche photodiode, for example. The photodiode PD described above is an example of a light receiving element. In addition, the circuit 10 (FIG. 9) is an example of a light receiving circuit. However, the light receiving circuit may be a circuit having a configuration different to this.

Note that there is no need for all of the plurality of light receiving circuits 11 provided in the light receiving apparatus 100 to be circuits for which it is possible to switch recharge methods (for example, the circuit 10). For example, in the light receiving apparatus, some of the plurality of light receiving circuits 11 may be circuits for which it is possible to switch recharge methods, with the remainder of the plurality of light receiving circuits 11 being passive recharge circuits (for example, the circuit 13). In other words, a light receiving apparatus according to the present disclosure may further include a plurality of second light receiving circuits configured to perform a passive recharge of a light receiving element. In addition, some of the light receiving circuits 11 of the light receiving apparatus may be active recharge circuits. Accordingly, a light receiving apparatus according to the present disclosure may further include a plurality of third light receiving circuits configured to perform an active recharge of a light receiving element.

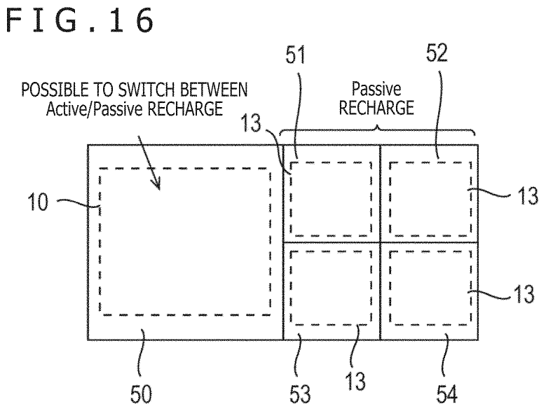

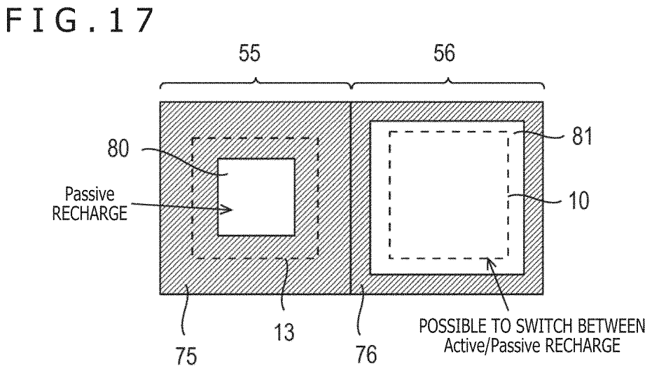

Plan views in FIG. 16 and FIG. 17 illustrate examples of the correspondence between pixels and a recharge circuit. FIG. 16 illustrates pixels 50 to 54. Of the pixels 50 to 54, the pixel 50 is mounted with a photodiode having a light receiving surface with a relatively large area. For example, it is possible to mount a photodiode having a circuit for which it is possible to switch recharge methods (for example, the circuit 10) to the pixel 50. In contrast, the pixels 51 to 54 are each mounted with a photodiode having a light receiving surface with a relatively small area. For example, it is possible to mount a photodiode having a passive recharge circuit (the circuit 13) to each of the pixels 51 to 54.

FIG. 17 illustrates a pixel 55 and a pixel 56. The pixel 55 is covered by a light-blocking section 75 having a relatively large area, and thus an area of an opening surface 80 has become smaller. For example, it is possible to mount a photodiode having a passive recharge circuit (the circuit 13) to the pixel 55. In contrast, the pixel 56 is covered by a light-blocking section 76 having a relatively small area, and thus an area of an opening surface 81 has become larger. For example, it is possible to mount a photodiode having a circuit able to switch recharge methods (for example, the circuit 10) to the pixel 56.

The probability that a light receiving circuit will detect a photon and enter the dead time depends on the area of the light receiving surface or the opening surface of a photodiode as well as the illuminance of the environment. Accordingly, as exemplified in FIG. 16 and FIG. 17, according to the area of the light receiving surface or the opening surface of a photodiode, it is possible to prepare a light receiving circuit for which the sensitivity is adjusted and which supports various illuminances. For example, it is possible to mount a circuit able to switch recharge methods (for example, the circuit 10) in a pixel for which a probability of entering the dead time is estimated to be relatively high, and mount a passive recharge circuit (for example, the circuit 13) in a pixel for which the probability of entering the dead time is estimated to be relatively low. In comparison to a case of mounting a circuit able to switch recharge methods in all pixels, it is possible to reduce power consumption and costs while photon detection accuracy is maintained.

In other words, in a light receiving apparatus according to the present disclosure, it may be that a first light receiving circuit is connected to a first pixel, and a second light receiving circuit is connected to a second pixel having a smaller light receiving surface or an opening surface than a light receiving surface or an opening surface of the first pixel.

The control circuit 40 can uniformly perform the same settings to the plurality of light receiving circuits 11. For example, the control circuit 40 can set the same recharge method to the plurality of light receiving circuits 11. However, the setting details for the plurality of light receiving circuits 11 do not need to be the same. For example, the control circuit 40 can set a different recharge method depending on the light receiving circuit 11. For example, it may be that a predetermined ratio of light receiving circuits 11 are caused to perform active recharge, and the remaining light receiving circuits 11 are caused to perform passive recharge. For example, it may be that active recharge is set to 40, of the light receiving circuits, and passive recharge is set to 60% of the light receiving circuits.

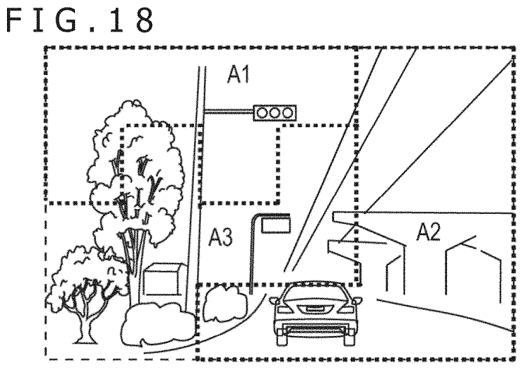

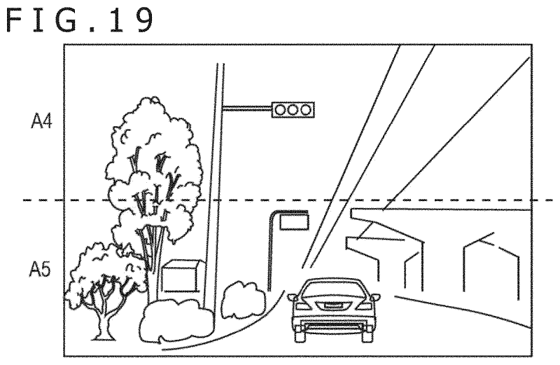

FIG. 18 illustrates an example of setting a distance measurement condition for each image region. In addition, FIG. 19 illustrates an example of setting a distance measurement condition for each image. FIG. 18 and FIG. 19 illustrate an image imaged by an automobile traveling following a highway viaduct. The image includes a region A1, a region A2, and a region A3. The region A1 corresponds to a sky portion and has a relatively high illuminance. The region A2 corresponds to a portion in shadow due to the viaduct and has relatively low illuminance. In addition, the region A3 corresponds to the remaining portion. The greater the illuminance of a region in the image, the more that the disturbance light at the time of the distance measurement increases. Accordingly, a recharge method for which it is possible to expect short the dead time is set for a light receiving circuit which images the region A1. A recharge method for which it is possible to expect suppression of power consumption is set for a light receiving circuit which images the region A2.

For example, it is possible to cause active recharge to be performed in a light receiving circuit which images the region A1. It is also possible to cause passive recharge to be performed in a light receiving circuit which images the region A2. It is possible to estimate the illuminance of each region in an image by the method described in relation to FIG. 13. For example, the histogram generator 31 can generate a histogram as in FIG. 13 for each group of light receiving circuits which image a respective region. It is possible to compare illuminances for a plurality of regions if the value of the vertical axes of the histograms is normalized by the number of light receiving circuits (pixels) which image a respective region.

In addition, it may be a parameter with which short the dead time can be expected is set to a light receiving circuit which images the region A1, and a parameter with which suppression of power consumption can be expected is set to a light receiving circuit which images the region A2. For example, for the region A1, the time delay td for the recharge pulse may be set to be short, or the recharge current may be set to be large. For example, for the region A2, the time delay td for the recharge pulse may be set to be long, or the recharge current may be set to be small.

Note that, in a case where there is a mixture of pixels where the illuminance is high and pixels where the illuminance is low as with the region A3 in FIG. 18, the recharge method for the light receiving circuits may be set in alignment with a pixel having the highest illuminance. As a result, it is possible to maintain high distance measurement accuracy. In addition, the recharge method for light receiving circuits for imaging the region A3 may be determined, on the basis of an average illuminance within the region A3.

In other words, the control circuit of a light receiving apparatus according to the present disclosure may be configured to control the recharge method for a first light receiving circuit for each region of a captured image.

Due to the functionality of the control circuit 40 or the topology of signal lines l_ct used for transmission of control signals, there are cases where only uniformly making the same setting for the plurality of light receiving circuits can be performed. In addition, there may also be implementations in which designation of a recharge method is performed in units of groups of light receiving circuits. Furthermore, there are cases in which avoiding complicating the control algorithm is desirable, irrespective of the granularity at which control is possible.

Accordingly, it is possible to set the same recharge method for an entire image. In a case of making distance measurement accuracy be the highest priority, the control circuit 40, in alignment with the light receiving circuit or group of light receiving circuits having measured the highest illuminance, determines the recharge method to be set to the plurality of light receiving circuits. In addition, it may be that an image region for which particularly high distance measurement accuracy is required is designated, and, in alignment with illuminance measured by a light receiving circuit which images this region, the recharge method to be set to the plurality of light receiving circuits is determined. For example, in application in a field of in-vehicle devices, it is possible to determine a distance measurement condition for an entire image in alignment with the illuminance measured in a region A5 in FIG. 17, in which there is a high possibility of other automobiles, pedestrians, animals, etc. appearing.

A region having a high possibility of other automobiles, pedestrians, animals, etc. appearing may be designated in advance on the basis of coordinates in the height direction in the image. In addition, the measurement circuit 30 may use machine learning such as a neural network to dynamically extract a region having a high possibility of another automobile, pedestrians, animals, etc. appearing in an image. In this case, the measurement circuit 30 may generate training data according to images obtained by a plurality of light receiving circuits (a plurality of SPADs). In addition, the measurement circuit 30 may generate training data according to an image imaged by another image sensor.

In other words, the control circuit of a light receiving apparatus according to the present disclosure may be configured so that the control circuit controls the recharge method for the plurality of first light receiving circuits on the basis of a signal outputted by a first light receiving circuit corresponding to a region of a portion of a captured image.

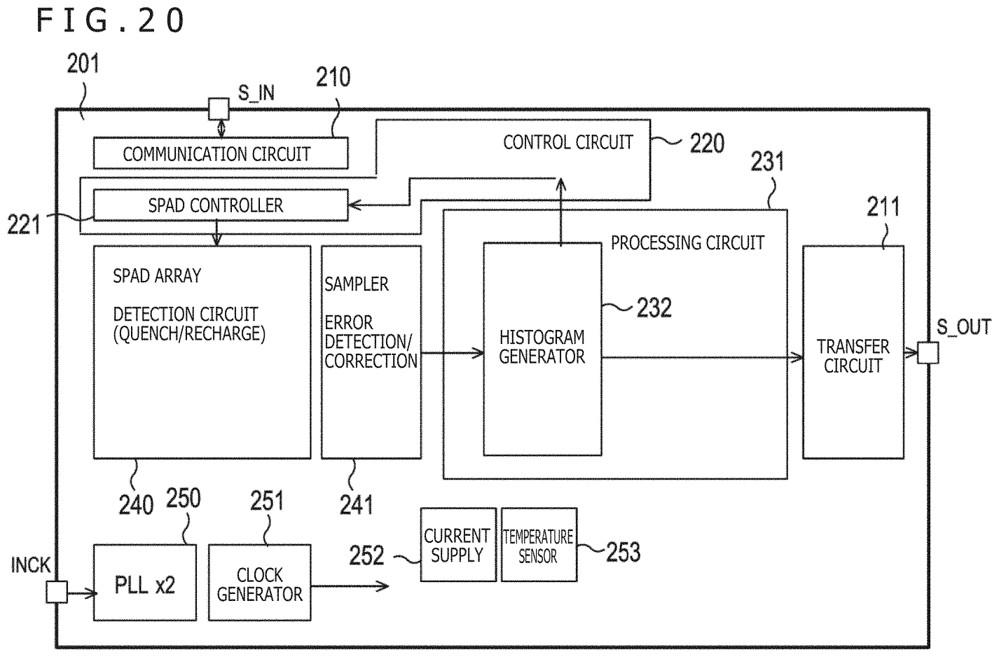

A light receiving apparatus according to the present disclosure may be a distance measurement apparatus including a light emitting element and a distance calculation section as with the apparatus illustrated in FIG. 1 and FIG. 2. However, a light receiving apparatus according to the present disclosure does not necessarily need to include a distance measurement function. For example, an apparatus in which the distance calculation section 233 and the trigger circuit 254 are omitted, as with a light receiving apparatus 201 in FIG. 20, may be used. The light receiving apparatus 201 can detect photons by the SPAD array, and generate the histogram in FIG. 13. It may be that the light receiving apparatus 201 is connected to another apparatus, and functionality corresponding to a distance calculation section, a trigger circuit, and a light emitting element is added. In addition, the light receiving apparatus 201 can be used as an apparatus for determining a recharge method. In this case, another distance measurement apparatus can measure distance on the basis of the recharge method determined by the light receiving apparatus 201.

Next, description is given regarding an example of a light receiving apparatus that performs an error determination on the basis of a voltage signal outputted from a light receiving circuit, and determines a recharge method.

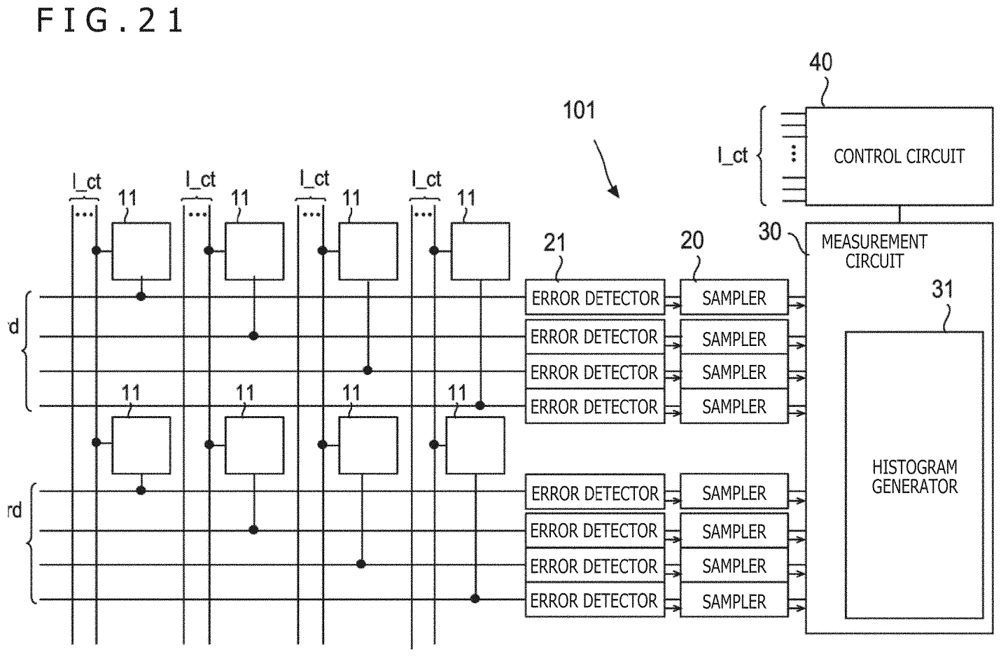

FIG. 21 is a schematic view illustrating an example of a light receiving apparatus according to a first modification. In a light receiving apparatus 101 in FIG. 21, error detectors 21 are connected between the light receiving circuits 11 and the samplers 20. Each error detector 21 is configured to perform an error detection on the basis of a voltage signal outputted from a light receiving circuit 11. The error detectors 21 are disposed in the circuit block 241 in FIG. 1 or FIG. 20, for example. At least some of the plurality of light receiving circuits 11 are made to be circuits for which switching the recharge method is possible (for example, the circuit 13). Some of the light receiving circuits 11 in the light receiving apparatus 101 may be passive recharge circuits or active recharge circuits.

Note that the light receiving apparatus configuration illustrated in FIG. 21 is merely an example. For example, the error detectors 21 may be connected between the samplers 20 and input terminals of the measurement circuit 30. In addition, a circuit in which functionality of a sampler 20 and functionality of an error detector 21 are integrated may be connected between respective light receiving circuits 11 and input terminals for the measurement circuit 30. In addition, functionality corresponding to the error detectors 21 may be implemented in the measurement circuit 30. In this case, it can be said that the measurement circuit 30 includes an error detector 21.

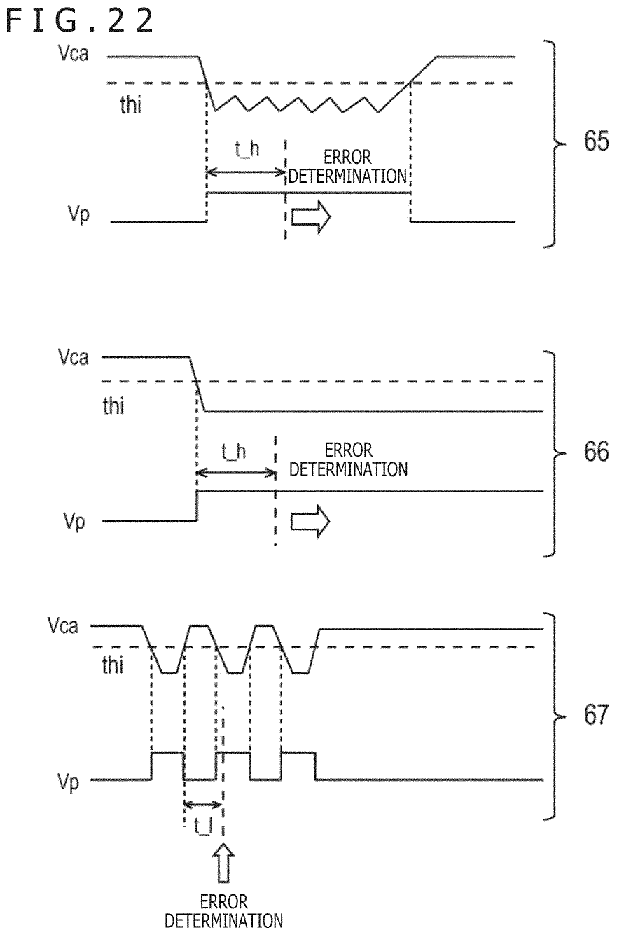

Graphs in FIG. 22 illustrate examples of the error detection by an error detector 21. Graphs 65 to 67 in FIG. 22 illustrate waveforms for the cathode potential Vca of the photodiode PD, and an output voltage Vp from the light receiving circuit 11 (inverter INV). In all of the graphs, the horizontal axis indicates time.

The graph 65 illustrates a case (a case similar to the graph 61 in FIG. 4) in which due to high illuminance, before the cathode potential Vca rises to a voltage higher than the threshold for the inverter INV, the photodiode PD re-reacts with a photon of disturbance light, and the pulse width outputted by the inverter INV becomes too large. For example, the error detector 21 detects the rising edge of a pulse in the voltage signal outputted from the light receiving circuit 11. The error detector 21 then monitors the pulse width. The error detector 21 performs an error determination in a case where the pulse width exceeds a threshold t_h. For example, the error detector 21 can sample the voltage of the signal at a period t_s, and perform an error determination once the sampled voltage is continuously HIGH n_h times. In this case, it is possible to set values for t_s and n_h such that the relation t_h=t_s×n_h is satisfied. In addition, error determination may be performed by a method differing to this.

In the graph 66, because the recharge current in the light receiving circuit 11 is too large, the voltage across the terminals of the photodiode PD does not decrease to the breakdown voltage, and quenching ceases to be possible. Accordingly, the output voltage of the light receiving circuit 11 is stuck (a case similar to the graph 62 in FIG. 43). For example, the error detector 21 detects the rising edge of a pulse in the voltage signal outputted from the light receiving circuit 11. The error detector 21 then measures the time period in which the output voltage from the light receiving circuit 11 is HIGH. The error detector 21 performs an error determination if the time period in which the output voltage from the light receiving circuit 11 is HIGH exceeds the threshold t_h. In the example of the graph 66, it is possible to perform an error determination by a similar method to that In a case of the graph 65.

In the graph 67, a residual charge occurs in the photodiode PD after a reaction with a photon. Accordingly, due to the light receiving circuit 11, a re-reaction with a photon occurs in the photodiode PD even if operations for quenching and recharging are being performed. The cathode potential Vca hunts due to the re-reaction with the photon. For example, the error detector 21 performs an error determination in a case where, after a falling edge of a pulse in the voltage signal from the light receiving circuit 11, at time period in which the output voltage from the light receiving circuit 11 is LOW is less than a threshold t_l. For example, the error detector 21 can sample the voltage of the signal at a period t_s, and perform an error determination in a case where the number of times the sampled voltage is continuously LOW is less than n_l. In this case, it is possible to set values for t_s and n_l such that a relation of t_1=t_s×n_l is satisfied. In addition, error determination may be performed by a method differing to this.

Description is given here for an error determination in a case where the light receiving circuit 11 outputs a HIGH level (positive polarity) pulse at a time of photon detection. The error detector 21 can also perform an error determination in a case where the light receiving circuit 11 outputs a LOW level (negative polarity) pulse. In this case, it is sufficient if the error detector 21 operates with, in the description given above, HIGH replaced with LOW, LOW replaced with HIGH, the falling edge of a pulse replaced with the rising edge of the pulse, and the rising edge of a pulse replaced with the falling edge of the pulse.

The error detector 21, in a case of having performed an error determination, transmits an error signal to the measurement circuit 30. For example, the error detector 21 may transmit the error signal using a signal line separate from a signal line on which a pulse is transmitted at a time of detection of a photon. Alternatively, the error detector 21 may transmit the error signal superimposed on the signal line on which a pulse is transmitted at a time of detection of a photon.

The error signal transmitted by the error detector 21 may include an error code. An error code is information for specifying the type of an error detected by the error detector 21. For example, it is possible to respectively associate error codes E1, E2, and E3 with errors in the graphs 65 to 67 described above. The measurement circuit 30 counts the number of error determinations for the plurality of light receiving circuits 11. In addition, in a case where error codes are included in error signals, the measurement circuit 30 may count the number of error determinations for each error code. In addition to an error code, the error detector 21 may transmit information relating to an error. For example, the error detector 21 can transmit, to the measurement circuit 30, information regarding an interval t_ip between pulses detected by using an error signal with the error code E3. The measurement circuit 30 transfers the counted number of error determinations to the control circuit 40.

The control circuit 40 can determine the recharge method on the basis of the number of error determinations for the plurality of light receiving circuits 11. For example, the control circuit 40 can change the recharge method In a case where the number of error determinations exceeds a threshold. In addition, the control circuit 40 may determine the recharge method on the basis of an error code included in an error signal. For example, the control circuit 40 can determine the recharge method on the basis of a ratio between respective error codes.

For example, in a case where the number of error determinations is greater than or equal to a threshold and the error code E1 is included at a predetermined ratio or greater in a plurality of error signals, the control circuit 40 can increase the recharge current at a time of passive recharge or change the recharge method to active recharge. In addition, in a case where the number of error determinations exceeds a threshold and a ratio for the error code E2 exceeds a predetermined value, the control circuit 40 can reduce the recharge current at a time of passive recharge or switch the recharge method to active recharge.

In a case where the number of error determinations exceeds a threshold and a ratio for the error code E3 exceeds a predetermined value when passive recharge is being performed by the plurality of light receiving circuits 11, the control circuit 40 can increase the recharge current. In a case where the number of error determinations exceeds a threshold and the ratio for the error code E3 exceeds a predetermined value when active recharge is being performed by the plurality of light receiving circuits 11, it is possible to execute different processing according to the detected interval t_ip between pulses. In a case where the difference between t_ip and a pulse delay td for active recharge is less than a predetermined value, the control circuit 40 can determine that a setting value td for pulse delay is too low and cause the control circuit 40 to change the pulse delay td to a larger value. In addition, in a case where the difference between t_ip and the pulse delay td for active recharge is greater than or equal to the predetermined value, the control circuit 40 can change the pulse delay td for active recharge to a smaller value.

In the above description, description is given for an example of a case where the control circuit 40 determines the recharge method on the basis of a ratio for an error code. However, the control circuit 40 may determine the recharge method by a method different to this. For example, the control circuit 40 can compare the number of error signals having a respective error code with a threshold, and determine the recharge method according to a determination result for the comparison.

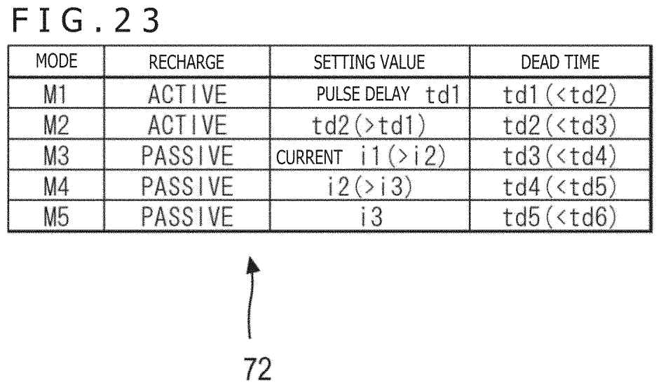

A table in FIG. 23 indicates an example of operation modes for the light receiving apparatus 101. In a table 72 in FIG. 23, five operation modes, M1 through M5, are defined. In the mode M1 and the mode M2, active recharge is performed. In the mode M2, a setting value for the active recharge pulse delay is larger in comparison to that for the mode M1. In the modes M3 through M5, passive recharge is performed. A setting value for recharge current gets larger in the order of the modes M5, M4, and M3. Accordingly, the length of the dead time expected in the light receiving circuit 11 gets shorter in the order of the modes M5, M4, M3, M2, and M1. However, power consumption increases in the order of the modes M5, M4, M3, M2, and M1.

A mode which defines a recharge method including parameters is used, whereby it is possible to avoid complicating processing executed by the measurement circuit 30 and the control circuit 40. For example, it may be that the measurement circuit 30 and the control circuit 40 switch the operation mode to thereby realize change of the recharge method as described above.

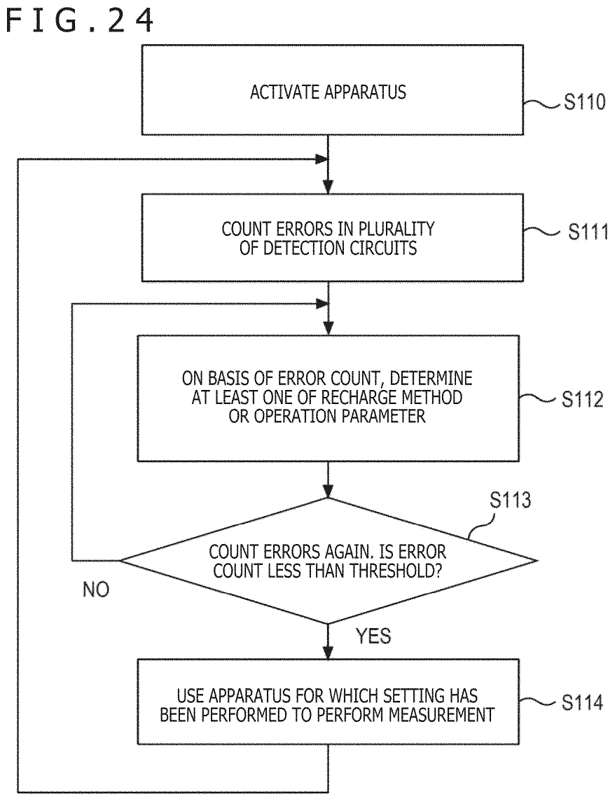

A flow chart in FIG. 24 illustrates an example of processing for determining a distance measurement condition according to the light receiving apparatus 101. The processing is described below with reference to the flow chart in FIG. 24.

At the start, electric power is supplied, and the light receiving apparatus 101 is activated (step S110). The light receiving apparatus 101 then counts errors for a plurality of light receiving circuits in a time period in which the light emitting element is not emitting light (step S111). In step S111, the measurement circuit 30 can receive an error signal from an error detector 21, and count errors on the basis of the error signal. For example, the measurement circuit 30 may obtain a total for the number of error determinations by receiving error signals. In addition, the measurement circuit 30 may obtain the number of error determinations for an individual error code. In such a manner, the measurement circuit 30 can count errors by various methods. The measurement circuit 30 transfers information regarding the number of error determinations to the control circuit 40.

Next, the control circuit 40, on the basis of error count, determines the recharge method to be used by a light receiving circuit 11 (step S112). The control circuit 40 then counts errors again in a state where the determined recharge method is being performed, and determines whether or not the error count is less than a threshold (step S113). Processing branches according to the determination result in step S113.

In a case where the detected error count is less than the threshold (YES in step S113), the measurement circuit 30 can performs a distance measurement on the basis of the setting determined in step S112 (step S114). In a case where the detected error count is greater than or equal to the threshold (NO in step 3113), the light receiving apparatus 101 returns to step S112. Note that, after the processing of step S114 is executed, the processing of step S111 and thereafter may be executed again in a time period in which a distance measurement (in other words, emission of light by the light emitting element) is not performed. As a result, it is possible to set the light receiving apparatus 101 in alignment with changes in illuminance of the environment.

It may be that the light receiving apparatus 101 is started up and determines an operation mode in an initial state for the light receiving apparatus 101 on the basis of the error count obtained in step S111. For example, the initial operation mode of the light receiving apparatus 101 may be set to the mode M1 in a case where the error count in step S111 is greater than a predetermined value. In addition, the initial operation mode of the light receiving apparatus 101 may be set to the mode M5 in a case where the error count in step S111 is less than the predetermined value.

The control circuit 40 may determine a changed operation mode on the basis of the operation mode for the initial state. For example, In a case where the initial operation mode is the mode M5, the operation mode may be changed to the mode M4 In a case where the error count is greater than or equal to a threshold. Similarly, in the mode M4 as well, the operation mode may be changed to the mode M3 In a case where the error count is greater than or equal to a threshold. In such a manner, it is possible to start a distance measurement processing after changing of the operation mode is repeatedly performed until the error count becomes less than a threshold. By this method, it is possible to achieve a balance between power consumption and distance measurement accuracy.

In addition, In a case where the operation mode in the initial state is the mode M1, the operation mode may be changed to the mode M2 In a case where the error count is less than a threshold. In the mode M2 as well, the operation mode may be changed to M3 in a case where the error count is less than a threshold. In such a manner, it may be that starting is performed in an operation mode for which expected the dead time is the shortest and, In a case where the error count is less than a threshold, an operation mode for which power consumption is more suppressed is changed to. When this method is used, it is possible to prevent power consumption becoming larger than necessary.

Note that the light receiving apparatus 101 does not necessarily need to be adjusted as described above. For example, it may be that the light receiving apparatus 101 obtains the error count in the operation mode for the initial state, and in a case where the error count is less than a threshold, immediately starts a distance measurement without changing the operation mode.

In the light receiving apparatus 101, it is possible to adjust settings for the plurality of light receiving circuits 11 in alignment with illuminance of the environment. As a result, it is possible to ensure a high distance measurement accuracy.

Note that the control circuit 40 of the light receiving apparatus 101 may set a recharge method which differs between light receiving circuits 11, similarly to with the light receiving apparatus 100. Similarly, the control circuit 40 of the light receiving apparatus 101 may set the same recharge method to the plurality of light receiving circuits 11. In addition, the control circuit 40 of the light receiving apparatus 101 may set parameters which differ between light receiving circuits 11. In other words, the control circuit 40 of the light receiving apparatus 101 may set the same operation mode to the plurality of light receiving circuits 11. In addition, the control circuit 40 of the light receiving apparatus 101 may set operation modes which differ between light receiving circuits 11.

A light receiving apparatus according to the present disclosure may further include an error detector configured to perform an error determination on the basis of the waveform of a signal outputted by a first light receiving circuit. In this case, the control circuit is configured to control the recharge method for at least one first light receiving circuit on the basis of the number of error determinations for signals outputted by the plurality of the first light receiving circuits. In addition, the error detector may be configured to perform an error determination for at least one of a signal having a pulse width in excess of a first threshold, or a signal having an interval between pulses of less than a second threshold. The threshold t_h described above is an example of the first threshold. In addition, the threshold t_l described above is an example of the second threshold.

Furthermore, the light receiving apparatus 101 may count errors for each image region and determine a distance measurement condition (for example, the recharge method) for each image region, as illustrated by FIG. 18. In addition, as illustrated by FIG. 19, the light receiving apparatus 101 may count errors for each image region and set the same distance measurement condition for the entire image on the basis of the result of the counting. The light receiving apparatus 101 may be a distance measurement apparatus including the light emitting element 255, a distance measurement section 234, and the trigger circuit 254. In addition, the light receiving apparatus 101 may be an apparatus which omits the light emitting element 255, the distance measurement section 234, and the trigger circuit 254.

Next, description is given regarding an example of a light receiving apparatus including a function for, in a case where an output signal from a light receiving circuit is subject to an error determination, correcting this signal.

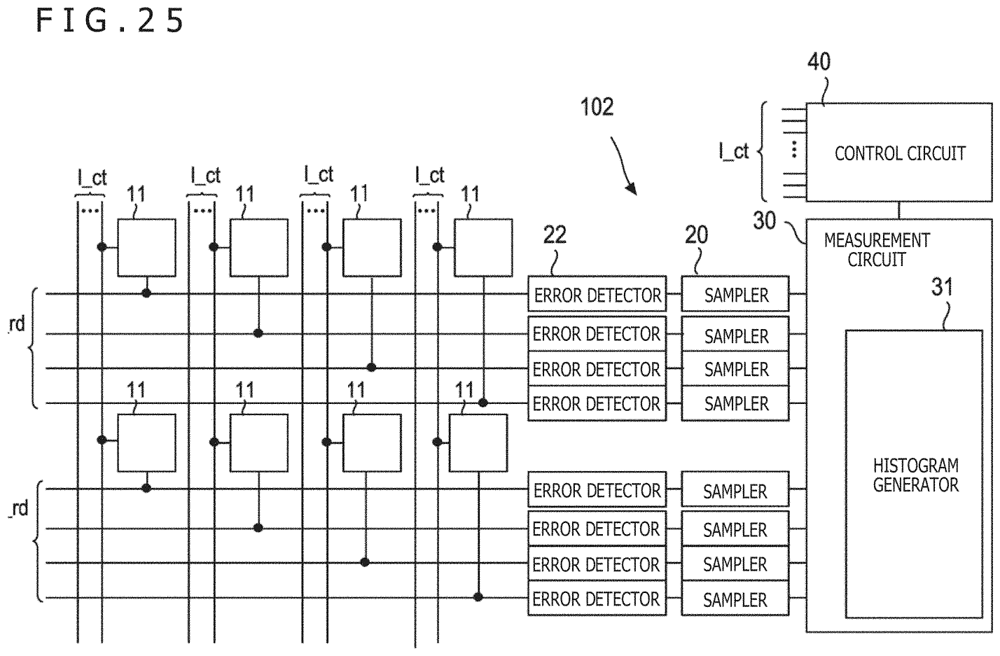

A schematic view in FIG. 25 illustrates an example of a light receiving apparatus according to a second modification. In a light receiving apparatus 102 in FIG. 25, error correction circuits 22 are connected between the light receiving circuits 11 and the samplers 20. Each error correction circuit 22 is configured to, from voltage signals outputted from a light receiving circuit 11, correct a voltage signal determined to be in an error state. Each error correction circuit 22 corresponds to a result of adding functionality, for converting a voltage signal which has been subjected to an error determination to a voltage signal which is not in an error state, to an error detector 21. The error correction circuits 22 are disposed in the circuit block 241 in FIG. 1 or FIG. 20, for example. The configuration and the functionality of the light receiving apparatus 102 is similar to that of the light receiving apparatus 101 described above, except for that the error detectors 21 are replaced by the error correction circuits 22.

Note that the light receiving apparatus configuration illustrated in FIG. 25 is merely an example. For example, the error correction circuits 22 may be connected between the samplers 20 and input terminals of the measurement circuit 30. In addition, a circuit in which functionality of a sampler 20 and functionality of an error correction circuit 22 are integrated may be connected between respective light receiving circuits 11 and input terminals for the measurement circuit 30. Note that functionality for converting a voltage signal which has been subjected to an error determination to a voltage signal not in an error state may be implemented on an input stage for the measurement circuit 30. In this case, the measurement circuit 30 can, on the basis of an error signal received from an error detector 21, correct a voltage signal outputted from a light receiving circuit 11. In other words, the measurement circuit 30 can employ a configuration which includes an error correction circuit 22.

At least some of the plurality of light receiving circuits 11 are made to be circuits for which switching the recharge method is possible (for example, the circuit 13). Note that some of the light receiving circuits 11 in the light receiving apparatus 101 may be passive recharge circuits or active recharge circuits.

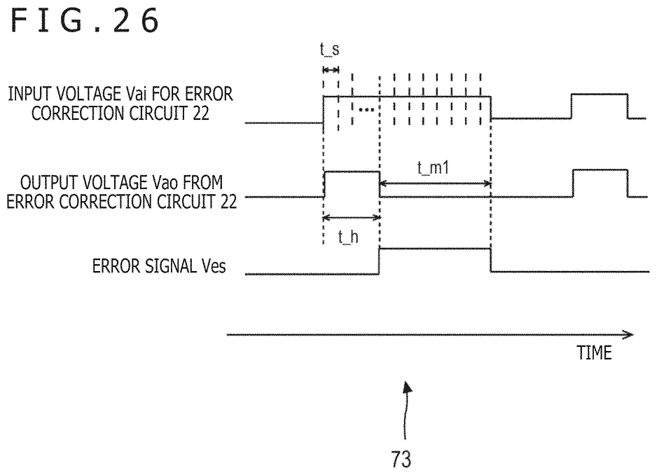

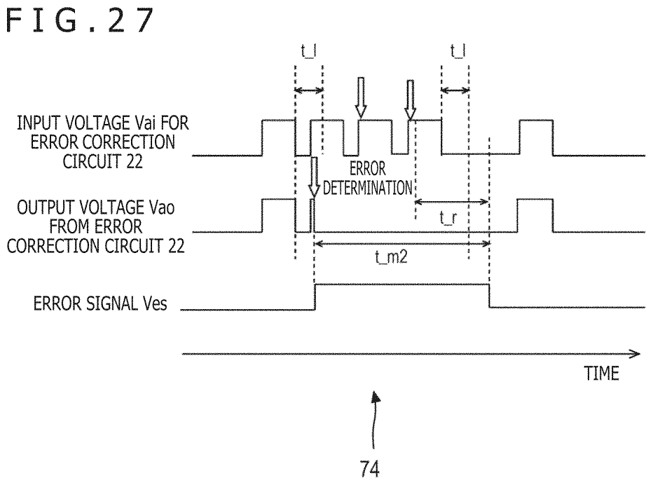

Graphs in FIG. 26 and FIG. 27 illustrate examples of processing for correcting a voltage waveform in the light receiving apparatus 102. In all of the graphs, the horizontal axis indicates time.

A graph 73 in FIG. 26 illustrates waveforms of an input voltage Vai for an error correction circuit 22, an output voltage Vao from the error correction circuit 22, and an error signal Ves. In the example in the graph 73, passive recharge is performed by a light receiving circuit 11, and a phenomenon similar to that in the graph 61 (FIG. 4) and the graph 65 (FIG. 22) occurs. In the graph 73, the pulse width outputted from the light receiving circuit 11 becomes too large. For example, the error correction circuit 22 detects the rising edge of a pulse in a voltage signal outputted from the light receiving circuit 11. The error correction circuit 22 then monitors the pulse width. The error correction circuit 22 outputs an inputted signal unchanged until an error determination is performed. The error correction circuit 22 performs an error determination in a case where the pulse width exceeds a threshold t_h. The error correction circuit 22, upon performing an error determination during detection of a pulse, masks a portion of the pulse in excess of the threshold t_h.

In the example of the graph 73, the error correction circuit 22 outputs a HIGH voltage in a portion for the time period t_h from the rising edge of the pulse. The error correction circuit 22 then outputs a LOW voltage in a portion for a time period t_m1 corresponding to after the pulse width exceeds t_h. In such a manner, even In a case the light receiving circuit 11 outputs a pulse having a pulse width exceeding the threshold t_h, the error correction circuit 22 can correct the pulse to a pulse for which the pulse width is equal to the threshold t_h. Note that, in the example of the graph 73, the voltage for the error signal Ves becomes HIGH in the time period t_m1 in which the pulse is masked. As a result, it becomes possible to perform a notification that an error determination has been performed to the measurement circuit 30 which is a subsequent stage. Note that the error correction circuit 22 may notify an error code to the measurement circuit 30. As a result, the control circuit 40 can determine the recharge method according to an error type and not just the number of error determinations.

The error correction circuit 22 can sample the input voltage Vai at a period t_s, and perform an error determination in a case where the sampled voltage is continuously at the HIGH level n_h times. Here, it is possible to set values for t_s and n_h such that the relation t_h=t_s−n_h is satisfied. For example, it is possible to set t_s=1 nanosecond, n_h=10, and t_h=10 nanoseconds. However, error determination may be performed by a method differing to this. Note that, even In a case where the phenomenon in the graph 62 (FIG. 4) and the graph 66 (FIG. 22) has occurred, the error correction circuit 22 can correct the waveform of a voltage signal, and output a pulse width for which the pulse width is equal to the threshold t_h.

A graph 74 in FIG. 27 illustrates waveforms of an input voltage Vai for an error correction circuit 22, an output voltage Vao from the error correction circuit 22, and an error signal Ves. In the example in the graph 74, active recharge is being performed by a light receiving circuit 11. In the example in the graph 74, the output voltage from the light receiving circuit 11 (in other words, the input voltage Vai for the error correction circuit 22) is hunting due to a phenomenon similar to that in the graph 67 (FIG. 22). The error correction circuit 22 outputs an inputted signal unchanged until an error determination is performed. For example, the error correction circuit 22 performs an error determination in a case where the input voltage Vai is LOW for a time period shorter than a threshold t_l after the falling edge of a pulse in the input voltage Vai. The error correction circuit 22 may, after performing the error determination, output a HIGH error signal Ves. In addition, the error correction circuit 22 may notify an error code to the measurement circuit 30. The error correction circuit 22 masks the pulse for a predetermined time period t_m2 after the error determination.

In the example in the graph 74, the error correction circuit 22 outputs a voltage at the LOW level in the time period t_m2 after the error determination. This time period t_m2 shall be referred to as a masking time period. When the masking time period t_m2 elapses after an error determination, the error correction circuit 22 outputs the inputted signal unchanged again. For example, in the graph 74, after the masking time period t_m2 elapses, the error correction circuit 22 outputs the pulse again. As the masking time period t_m2, for example, it is possible to set a value which is larger than the threshold t_l.

In addition, the error correction circuit 22 may adjust the masking time period t_m2 according to a situation of error determinations for the input voltage Vai. For example, in the input voltage Vai in the graph 74, after the arrival of the first pulse, three pulses arrive at intervals shorter than the threshold t_l. Accordingly, the error correction circuit 22 performs an error determination three times successively at timings indicated by white arrows. However, the error correction circuit 22 can release the error state in a case where an error determination is not performed in a time period t r after the final error determination is performed. After the error state is released, the error correction circuit 22 outputs the inputted pulse unchanged again. As in the example in the graph 74, the error correction circuit 22 may set the error signal Ves to LOW when the error state is released. Note that the error correction circuit 22 may, for the duration of the time period t_m2, output a discontinuous HIGH error signal Ves each time an error determination is performed in place of continuously outputting a HIGH error signal Ves.

For example, the error correction circuit 22 can sample the voltage of the signal at a period t_s, and perform an error determination in a case where the number of times the sampled voltage is continuously LOW is less than n_l. It is possible to set values for t_s and n_l so that the relation of t_l=t_s×n_l is satisfied. However, the error correction circuit 22 may perform an error determination by a method different to this.

Description is given here regarding error determination and error correction in a case where the light receiving circuit 11 outputs a HIGH level (positive polarity) pulse at a time of photon detection. However, the error correction circuit 22 can also perform an error determination in a case where the light receiving circuit 11 outputs a LOW level (negative polarity) pulse. In this case, it is sufficient if the error correction circuit 22 operates with, in the description given above, HIGH replaced with LOW, LOW replaced with HIGH, the falling edge of a pulse replaced with the rising edge of the pulse, and the rising edge of a pulse replaced with the falling edge of the pulse.

A light receiving apparatus according to the present disclosure may further include an error correction circuit configured to, on the basis of the waveform of a signal outputted by a first light receiving circuit, perform an error determination and correct the waveform of the signal for which the error determination is performed. In addition, the error correction circuit may be configured to perform an error determination for at least one of a signal having a pulse width in excess of a first threshold, or a signal having an interval between pulses of less than a second threshold. Furthermore, the control circuit may be configured to control the recharge method for at least one first light receiving circuit on the basis of the number of error determinations for signals outputted by the plurality of the first light receiving circuits.

FIG. 9 illustrates the circuit 10 which is capable of switching a recharge method. However, the circuit 10 is merely an example of a circuit capable of switching the recharge method. Accordingly, a circuit capable of switching the recharge method may have a configuration different to this.

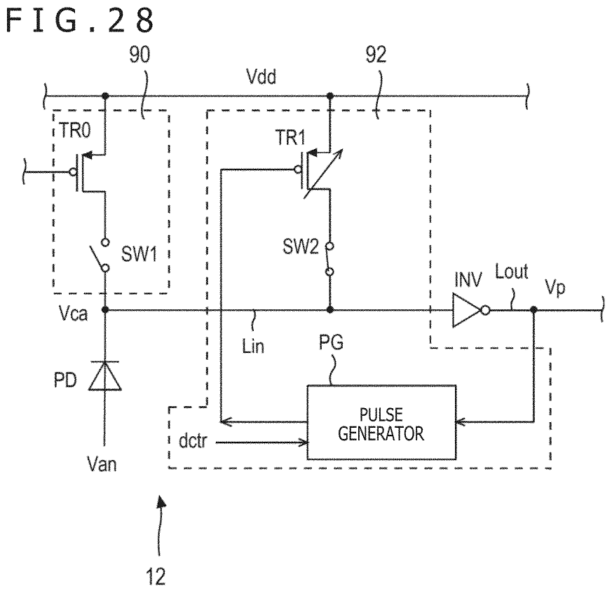

The circuit diagram in FIG. 28 illustrates an example of a circuit according to a third modification. A circuit 12 in FIG. 28 corresponds to a circuit resulting from omitting the transistor TR2 and the switch SW3 in the circuit 10. In other words, in the circuit 12, a portion from the circuit 10 for latching the state of the transistor TR1 is omitted. In the circuit 12, passive recharge is performed when SW1 is set to on and SW2 is set to off. In addition, in the circuit 12, active recharge is performed when SW1 is set to off and SW2 is set to on. Note that, in the circuit 12, when both of SW1 and SW2 are set to on, both of passive recharge and active recharge are performed. Note that operation of the circuit 12 is similar to that of the circuit 10 described above except that there ceases to be an operation for latching the state of the transistor TR1.

A light receiving circuit according to the present disclosure may include a light receiving element, a load element, a first switch, an inverter, a first transistor, a second switch, and a pulse generator. The load element is connected to a reference potential. The first switch is connected between the load element and the light receiving element. The inverter is connected to a first signal line between the first switch and the light receiving element via a second signal line. The first transistor is connected to the reference potential. The second switch is connected between the first transistor and the second signal line. The pulse generator is connected to a third signal line which is a subsequent stage for the inverter, and to a first control electrode of the first transistor.

Here, the photodiode PD is an example of the light receiving element. The light receiving element may be an avalanche photodiode. The transistor TR0 in FIG. 9 and FIG. 28 is an example of the load element. The power supply potential Vdd is an example of the reference potential. The switch SW1 is an example of the first switch. The transistor TR1 is an example of the first transistor. The switch SW2 is an example of the second switch. The first signal line corresponds to the signal line which continues between the switch SW1 and the photodiode PD, for example. The signal line Lin is an example of the second signal line. The signal line Lout is an example of the third signal line. The gate of the transistor TR1 is an example of the first control electrode of the first transistor.

The pulse generator may be configured to output a pulse to the first control electrode according to the voltage of the third signal line. In addition, the pulse generator may be configured to, when the voltage level of the third signal line changes, output a pulse to the first control electrode with a time delay. The pulse generator may be configured to adjust the time delay according to a control signal supplied from a control circuit. A pulse generator having any circuit configuration may be used.

In addition, a light receiving circuit according to the present disclosure may further include a second transistor connected to the reference potential, and a third switch connected between the second transistor and the second signal line. In this case, a second control electrode of the second transistor is connected to the third signal line. The transistor TR2 in FIG. 9 is an example of the second transistor. The switch SW3 in FIG. 9 is an example of the third switch. In addition, the second control electrode of the second transistor corresponds to the gate of the transistor TR2, for example.

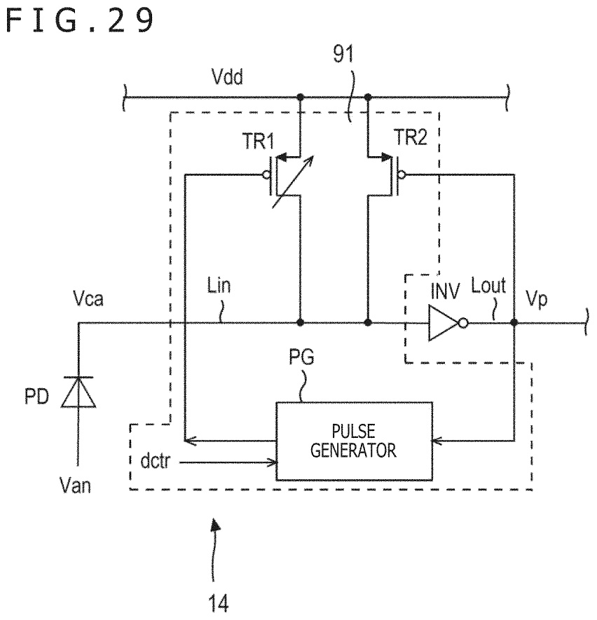

A circuit 14 in FIG. 29 corresponds to a circuit resulting from omitting the load element 90 (the transistor TR0) from the circuit 10. In other words, the circuit 14 is an active recharge circuit that does not perform passive recharge. Operation of the circuit 14 is similar to the case in which, in the circuit 10, the switch SW1 is set to off, the switch SW2 is set to on, and the switch SW3 is set to on (the switch setting st1 in the table 70).

At least one of the plurality of light receiving circuits 11 in the light receiving apparatuses 100 to 102 described above (FIG. 8, FIG. 21, and FIG. 25) may be the circuit 12 or the circuit 14. In this case, the control circuit 40 can switch the switch SW1 and the switch SW2, and control the signal supplied to the signal line dctr. In addition, at least one of the above-described circuit 10, circuit 12, or circuit 13 may be included in the plurality of light receiving circuits 11. As described above, it is possible to determine the type of a circuit used as a light receiving circuit 11 on the basis of the area of the light receiving surface or the opening surface of a photodiode (the probability that the photodiode will enter the dead time). For example, it is possible to install the circuit 14 (an active recharge circuit) in a pixel for which the area of the light receiving surface or the opening surface is large.

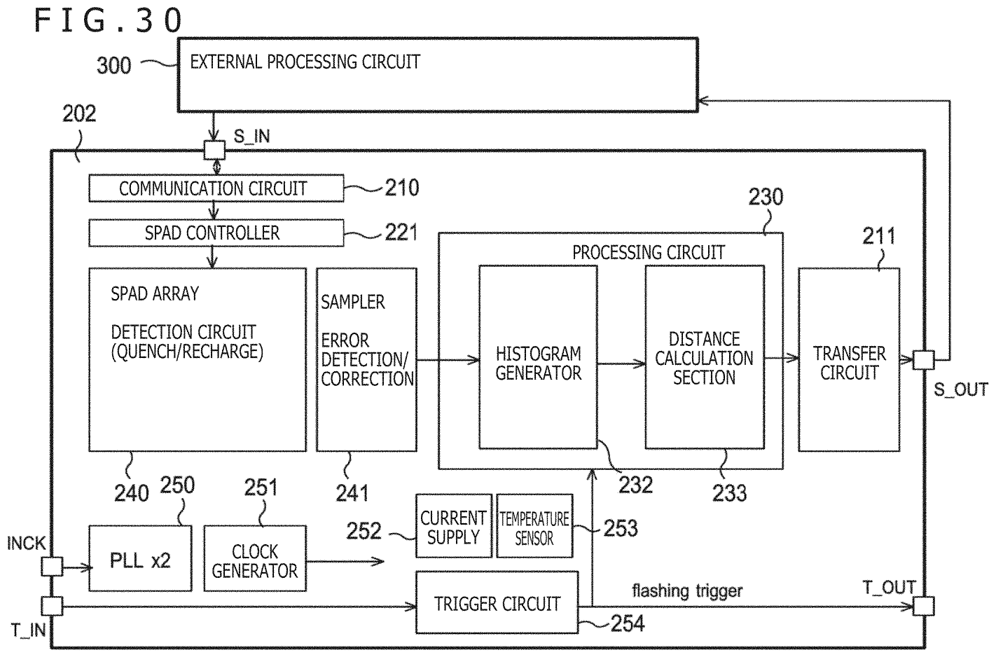

A block view in FIG. 30 illustrates an example of a distance measurement apparatus. FIG. 30 illustrates a distance measurement apparatus 202 and an external processing circuit 300. The distance measurement apparatus 202 corresponds to a result of omitting the control circuit 220 from components of the distance measurement apparatus 200 (FIG. 1). The processing circuit 230 of the distance measurement apparatus 202 is connected to the external processing circuit 300 via the transfer circuit 211 and a terminal S_OUT. In addition, the SPAD controller 221 of the distance measurement apparatus 202 is connected to the external processing circuit 300 via a terminal S_IN and the communication circuit 210. The external processing circuit 300 is a hardware circuit which is an ASIC or an FPGA, for example. However, the external processing circuit 300 may be a computer including a CPU (central processing unit) and a storage. In this case, the processing circuit 300 provides various functionality by a program stored in the storage being executed by the CPU.

The external processing circuit 300 executes functionality corresponding to the control circuit 220 in FIG. 1 (the control circuit 40 in FIG. 8, FIG. 21, and FIG. 25). In other words, with the distance measurement apparatus 202, the separate external processing circuit 300 may determine the recharge method for each light receiving circuit 11. For example, the external processing circuit 300 may receive, from the processing circuit 230, the number Nr of reacting SPADs obtained in a time period in which the light emitting element is not emitting light, and determine, on the basis of the number Nr of reacting SPADs, the recharge method for each light receiving circuit 11 (a method for FIG. 13 through FIG. 15). In addition, the external processing circuit 300 may determine the recharge method for each light receiving circuit 11 on the basis of an error count (a method for FIG. 24).

Note that communication between the processing circuit 300 and the distance measurement apparatus 202 may be performed over wire or may be performed wirelessly. In addition, the processing circuit 300 may determine the recharge method for each light receiving circuit 11 on the basis of the number Nr of reacting SPADs or an error count, determined for each image region (a method for FIG. 18 and FIG. 19).

By using a light receiving apparatus, a light receiving circuit, and a distance measurement apparatus according to the present disclosure, it is possible to determine a recharge method to use in alignment with the illuminance of the environment. Accordingly, it is possible to detect a photon and perform a distance measurement with high accuracy irrespective of the illuminance of the environment.

In addition, a light receiving apparatus, a light receiving circuit, and a distance measurement apparatus according to the present disclosure can perform passive recharge in a case where it is determined that there is no necessity to perform active recharge. Furthermore, it is also possible to suppress the recharge current at a time of passive recharge, or increase the time delay at which a pulse for active recharge is generated. Accordingly, it is possible to suppress power consumption necessary for a photon detection or a distance measurement. Furthermore, in a light receiving apparatus, a light receiving circuit, and a distance measurement apparatus according to the present disclosure, because it is possible to, for each imaged image region, perform a determination and determine a recharge method or a parameter for a time of recharge, it is possible to achieve optimal performance in alignment with an intended use.

The technique as in the present disclosure (the present technique) can be applied to various products. For example, the technique as in the present disclosure can be realized as an apparatus mounted to any of various types of mobile body, such as an automobile, an electric automobile, a hybrid electric vehicle, a motorcycle, a bicycle, personal mobility, an airplane, a drone, a ship, or a robot.

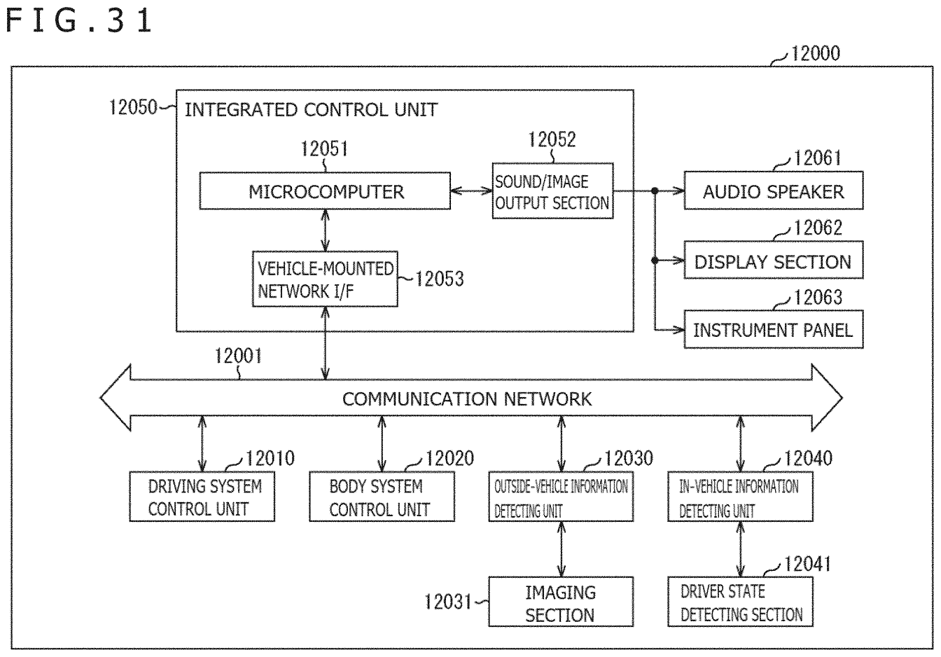

FIG. 31 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 31, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, or a driving motor, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, or a fog lamp. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information regarding the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the captured image. On the basis of the received image, the outside-vehicle information detecting unit 12030 may perform processing of detecting an object such as a human, a vehicle, an obstacle, a sign, or a character on a road surface, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information regarding a measured distance. In addition, the light received by the imaging section 12031 may be visible light, or may be invisible light such as infrared rays.

The in-vehicle information detecting unit 12040 detects information regarding the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information regarding the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automatic driving, which makes the vehicle to travel autonomously without depending on the operation of the driver, or the like, by controlling the driving force generating device, the steering mechanism, the braking device, or the like on the basis of the information regarding the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information regarding the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 31, an audio speaker 12061, a display section 12062, and an instrument panel 12063 are illustrated as the output device. The display section 12062 may, for example, include at least one of an on-board display and a head-up display.

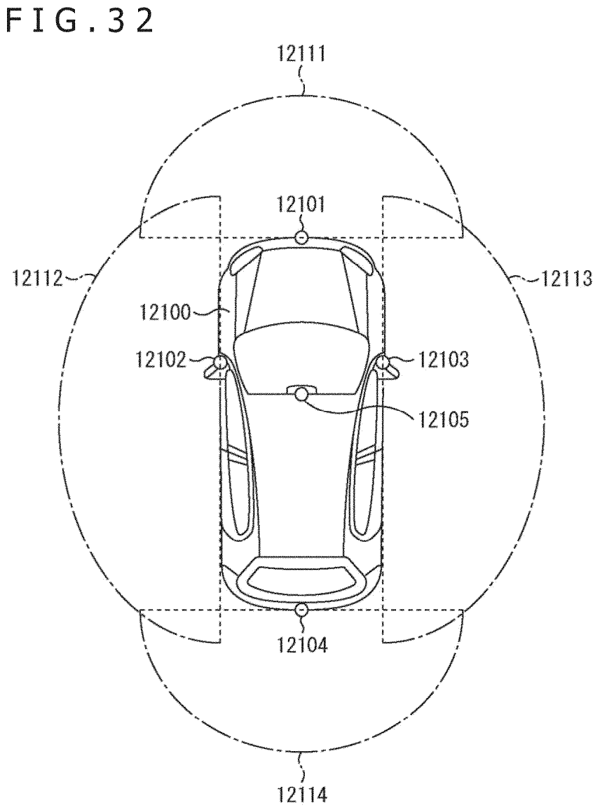

FIG. 32 is a diagram depicting an example of the installation position of the imaging section 12031.

In FIG. 32, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 32 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automatic driving that makes the vehicle travel autonomously without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the captured images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the captured images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

Description is given above regarding an example of a vehicle control system to which the technique as in the present disclosure can be applied. The technique as in the present disclosure can be applied to the imaging section 12031. For example, it is possible to implement the distance measurement apparatus 200 in FIG. 1 and the light emitting element 255 in FIG. 2 in the imaging section 12031. In addition, at least one of the light receiving apparatus 100 in FIG. 8, the light receiving apparatus 201 in FIG. 20, the light receiving apparatus 101 in FIG. 21, the light receiving apparatus 102 in FIG. 25, and the external processing circuit 300 and the distance measurement apparatus 202 in FIG. 30 may be implemented in the imaging section 12031. The technique as in the present disclosure is applied to the imaging section 12031 whereby it is possible to perform a distance measurement with high accuracy irrespective of the illuminance of the environment. As a result, it becomes possible to improve a safety of the vehicle 12100.

Note that the present technique can have the following configuration.

(1)

A light receiving apparatus including:

a first light receiving circuit configured such that a recharge method for a light receiving element can be switched; and

a control circuit configured so as to control the recharge method for the first light receiving circuit on the basis of a signal outputted by the first light receiving circuit in a reaction with a photon.

(2)

The light receiving apparatus according to (1), in which

the recharge method includes at least one of passive recharge, active recharge, or a combination of passive recharge and active recharge.

(3)

The light receiving apparatus according to (1) or (2), in which

the recharge method includes at least one of a recharge current for a time of passive recharge operation, or a time delay at which a reset pulse is generated at a time of active recharge operation.

(4)

The light receiving apparatus according to one of (1) through (3), further including:

a plurality of the first light receiving circuits, in which

the control circuit is configured to control the recharge method for at least one of the first light receiving circuits on the basis of the signal outputted by the plurality of the first light receiving circuits.

(5)

The light receiving apparatus according to (4), further including:

a measurement circuit configured to count the number of reactions in the plurality of the first light receiving circuits, in which

the control circuit is configured to control the recharge method for at least one first light receiving circuit on the basis of the number of reactions.

(6)

The light receiving apparatus according to (4) or (5), further including:

an error detector configured to perform an error determination on the basis of a waveform of the signal outputted by the first light receiving circuit, in which

the control circuit is configured to control the recharge method for at least one of the first light receiving circuits on the basis of the number of error determinations for the signal outputted by the plurality of the first light receiving circuits.

(7)

The light receiving apparatus according to (6), in which

the error detector is configured to perform an error determination for at least one of the signal having a pulse width in excess of a first threshold, or the signal having an interval between pulses of less than a second threshold.

(8)

The light receiving apparatus according to (4) or (5), in which

an error correction circuit configured to perform an error determination on the basis of the waveform of the signal outputted by the first light receiving circuit, and correct the waveform of the signal for which the error determination is performed.

(9)

The light receiving apparatus according to (8), in which

the error correction circuit is configured to perform an error determination for at least one of the signal having a pulse width in excess of a first threshold, or the signal having an interval between pulses of less than a second threshold.

(10)

The light receiving apparatus according to (8) or (9), in which

the control circuit is configured to control the recharge method for at least one of the first light receiving circuits on the basis of the number of error determinations for the signal outputted by the plurality of the first light receiving circuits.

(11)

The light receiving apparatus according to one of (4) through (10), in which

the control circuit is configured to control the recharge method for the first light receiving circuit for each region of a captured image.

(12)

The light receiving apparatus according to one of (4) through (10), in which

the control circuit is configured to control the recharge method for the plurality of the first light receiving circuits on the basis of the signal outputted by the first light receiving circuit that corresponds to a partial region of a captured image.

(13)

The light receiving apparatus according to one of (4) through (12), further including:

a plurality of second light receiving circuits configured to perform a passive recharge operation.

(14)

The light receiving apparatus according to (13), in which

each first light receiving circuit is connected to a first pixel, and

each second light receiving circuit is connected to a second pixel having a smaller light receiving surface or an opening surface than a light receiving surface or an opening surface of the first pixel.

(15)

The light receiving apparatus according to one of (1) through (14), in which

the light receiving element is an avalanche photodiode.

(16)

A distance measurement apparatus including:

a light emitting element;

a plurality of light receiving circuits configured such that a recharge method for a light receiving element can be switched; and

a control circuit configured to, in a time period in which the light emitting element is not emitting light, control the recharge method for at least one of the light receiving circuits on the basis of a signal outputted by the plurality of the light receiving circuits in reaction to a photon.

(17)

A light receiving circuit including:

a light receiving element;

a load element connected to a reference potential;

a first switch connected between the load element and the light receiving element;

an inverter connected to a first signal line between the first switch and the light receiving element via a second signal line;

a first transistor connected to the reference potential;

a second switch connected between the first transistor and the second signal line; and

a pulse generator connected to a third signal line that is a subsequent stage for the inverter, and a first control electrode of the first transistor.

(18)

The light receiving circuit according to (17), in which

the pulse generator is configured to output a pulse to the first control electrode according to a voltage of the third signal line.

(19)

The light receiving circuit according to (18), in which

the pulse generator is configured to, when a voltage level of the third signal line changes, output a pulse to the first control electrode with a time delay.

(20)

The light receiving circuit according to one of (17) through (19), further including:

a second transistor connected to the reference potential; and

a third switch connected between the second transistor and the second signal line, in which

a second control electrode of the second transistor is connected to the third signal line.

Aspects of the present disclosure are not limited to each embodiment described above and include various modifications which a person skilled in the art could conceive of. The effect of the present disclosure is also not limited to the details described above. In other words, various additions, modifications and partial deletions are possible without departing from the conceptual idea and gist of the present disclosure derived from the contents defined in the claims and their equivalents.

### REFERENCE SIGNS LIST

OBJ: Object
1: Detecting section
10, 12, 13: Circuit
11: Light receiving circuit
20: Sampler
21: Error detector
22: Error correction circuit
30: Measurement circuit
40: Control circuit
50, 51, 52, 53, 54, 55, 56: Pixel
75, 76: Light-blocking section
80, 81: Opening surface
90: Load element
91, 91, 92: Active recharge circuit
100, 101, 102: Light receiving apparatus
200: Distance measurement apparatus
255: Light emitting element

1. A light receiving apparatus comprising:
a first light receiving circuit configured such that a recharge method for a light receiving element is switched; and
a control circuit configured so as to control the recharge method for the first light receiving circuit on a basis of a signal outputted by the first light receiving circuit in a reaction with a photon.

2. The light receiving apparatus according to claim 1, wherein
the recharge method includes at least one of passive recharge, active recharge, or a combination of passive recharge and active recharge.

3. The light receiving apparatus according to claim 1, wherein
the recharge method includes at least one of a recharge current for a time of passive recharge operation, or a time delay at which a reset pulse is generated at a time of active recharge operation.

4. The light receiving apparatus according to claim 1, further comprising:
a plurality of the first light receiving circuits, wherein
the control circuit is configured to control the recharge method for at least one of the first light receiving circuits on a basis of the signal outputted by the plurality of the first light receiving circuits.

5. The light receiving apparatus according to claim 4, further comprising:
a measurement circuit configured to count the number of reactions in the plurality of the first light receiving circuits, wherein
the control circuit is configured to control the recharge method for at least one first light receiving circuit on a basis of the number of reactions.

6. The light receiving apparatus according to claim 4, further comprising:
an error detector configured to perform an error determination on a basis of a waveform of the signal outputted by the first light receiving circuit, wherein
the control circuit is configured to control the recharge method for at least one of the first light receiving circuits on a basis of the number of error determinations for the signal outputted by the plurality of the first light receiving circuits.

7. The light receiving apparatus according to claim 6, wherein
the error detector is configured to perform an error determination for at least one of the signal having a pulse width in excess of a first threshold, or the signal having an interval between pulses of less than a second threshold.

8. The light receiving apparatus according to claim 4, further comprising:
an error correction circuit configured to perform an error determination on a basis of the waveform of the signal outputted by the first light receiving circuit, and correct the waveform of the signal for which the error determination is performed.

9. The light receiving apparatus according to claim 8, wherein
the error correction circuit is configured to perform an error determination for at least one of the signal having a pulse width in excess of a first threshold, or the signal having an interval between pulses of less than a second threshold.

10. The light receiving apparatus according to claim 8, wherein
the control circuit is configured to control the recharge method for at least one of the first light receiving circuits on a basis of the number of error determinations for the signal outputted by the plurality of the first light receiving circuits.

11. The light receiving apparatus according to claim 4, wherein
the control circuit is configured to control the recharge method for the first light receiving circuit for each region of a captured image.

12. The light receiving apparatus according to claim 4, wherein
the control circuit is configured to control the recharge method for the plurality of the first light receiving circuits on a basis of the signal outputted by the first light receiving circuit that corresponds to a partial region of a captured image.

13. The light receiving apparatus according to claim 4, further comprising:
a plurality of second light receiving circuits configured to perform passive recharge of the light receiving element.

14. The light receiving apparatus according to claim 13, wherein
each first light receiving circuit is connected to a first pixel, and
each second light receiving circuit is connected to a second pixel having a smaller light receiving surface or an opening surface than a light receiving surface or an opening surface of the first pixel.

15. The light receiving apparatus according to claim 1, wherein
the light receiving element is an avalanche photodiode.

16. A distance measurement apparatus comprising:
a light emitting element;
a plurality of light receiving circuits configured such that a recharge method for a light receiving element is switched; and
a control circuit configured to, in a time period in which the light emitting element is not emitting light, control the recharge method for at least one of the light receiving circuits on a basis of a signal outputted by the plurality of the light receiving circuits in reaction to a photon.

17. A light receiving circuit comprising:
a light receiving element;
a load element connected to a reference potential;
a first switch connected between the load element and the light receiving element;
an inverter connected to a first signal line between the first switch and the light receiving element via a second signal line;
a first transistor connected to the reference potential;
a second switch connected between the first transistor and the second signal line; and
a pulse generator connected to a third signal line that is a subsequent stage for the inverter, and a first control electrode of the first transistor.

18. The light receiving circuit according to claim 17, wherein
the pulse generator is configured to output a pulse to the first control electrode according to a voltage of the third signal line.

19. The light receiving circuit according to claim 18, wherein
the pulse generator is configured to, when a voltage level of the third signal line changes, output a pulse to the first control electrode with a time delay.

20. The light receiving circuit according to claim 17, further comprising:
a second transistor connected to the reference potential; and
a third switch connected between the second transistor and the second signal line, wherein
a second control electrode of the second transistor is connected to the third signal line.
